(19) United States
(12) Patent Application Publication
(10) Pub. No.: US 2017/0295671 A1
(43) Pub. Date: Oct. 12, 2017

(54) MULTI-PHASE HEAT DISSIPATING DEVICE FOR AN ELECTRONIC DEVICE

(71) Applicant: QUALCOMM Incorporated, San Diego, CA (US)

(72) Inventors: Victor Adrian Chiriac, San Diego, CA (US); Jorge Rosales, San Diego, CA (US); Stephen Arthur Molloy, Carlsbad, CA (US); Jon Anderson, Boulder, CO (US)

(21) Appl. No.: 15/230,114

(22) Filed: Aug. 5, 2016

Related U.S. Application Data
(60) Provisional application No. 62/321,090, filed on Apr. 11, 2016.

(51) Int. Cl. H05K 7/20; G06F 1/20

(52) U.S. Cl. CPC H05K 7/20309; H05K 7/20318; G06F 1/203; H05K 7/208

(57) ABSTRACT

A device that includes a region comprising an integrated device, and a heat dissipating device coupled to the region comprising the integrated device. The heat dissipating device is configured to dissipate heat away from the region. The heat dissipating device includes a fluid, an evaporator configured to evaporate the fluid, a condenser configured to condense the fluid, an inner wall coupled to the evaporator and the condenser, an outer shell encapsulating the fluid, the evaporator, the condenser and the inner wall, an evaporation portion configured to channel an evaporated fluid from the evaporator to the condenser, wherein the evaporation portion is at least partially defined by the inner wall, and a collection portion configured to channel a condensed fluid from the condenser to the evaporator, wherein the collection portion is at least partially defined by the inner wall. The heat dissipating device may be a multi-phase heat dissipating device.

### CROSS-REFERENCE CLAIM OF PRIORITY TO RELATED APPLICATION

The present application claims priority to U.S. Provisional Application No. 62/321,090 titled “MULTI-PHASE HEAT DISSIPATING DEVICE FOR AN ELECTRONIC DEVICE”, filed Apr. 11, 2016, which is hereby expressly incorporated by reference herein.

### BACKGROUND

### Field

Various features relate a heat dissipating device, and more specifically to a multi-phase heat dissipating device for an electronic device.

### Background

Electronic devices include internal components that generate heat. Some of these internal components include a central processing unit (CPU), a graphics processing unit (GPU) and/or memory. Some of these internal components can generate a lot of heat. Specifically, a high performance CPU and/or GPU of an electronic device can generate a lot of heat, especially when performing data intensive operations (e.g., games, processing video).

To counter or dissipate the heat generated by the CPU and/or GPU, an electronic device may include a heat dissipating device, such as a heat spreader. FIGS. 1-3 illustrate an example of a mobile device that includes a heat spreader for dissipating heat generated by a chip. As shown in FIGS. 1 and 2, the mobile device 100 includes a display 102, a back side surface 200, a die 202, and a heat spreader 204. The die 202 and the heat spreader 204, which are both shown with dotted lines, are located inside the mobile device 100. The die 202 is coupled to a first surface of the heat spreader 204. A second surface of the heat spreader 204 is coupled to sa first surface (e.g., inner surface) of the back side surface 200.

FIG. 3 illustrates a profile view of the mobile device 100 that includes the heat spreader 204. As shown in FIG. 3, the mobile device 100 includes the display 102, the back side surface 200, a front side surface 300, a bottom side surface 302, and a top side surface 304. FIG. 3 also illustrates a printed circuit board (PCB) 306, the die 202 and the heat spreader 204 inside the mobile device 100.

As further shown in FIG. 3, a first side of the die 202 is coupled to a first surface of the PCB 306. A second side of the die 202 is coupled to a first surface of the heat spreader 204. A second surface of the heat spreader 204 is coupled to a first surface (e.g., inner surface) of the back side surface 200. In this configuration, almost all of the heat that is generated by the die 202 is dissipated through the heat spreader 204 and the back side surface 200 of the mobile device. However, the heat spreader 204 has limitation, including its limited heat dissipating capabilities. For example, the heat spreader 204 implemented in a mobile device, may be limited to dissipate away about 3 Watts of heat.

Therefore, there is a need for an improved method and design for efficiently dissipating heat from an electronic device (e.g., mobile device), while at the same time keeping the temperature of the outer surface of the electronic device within a threshold that is acceptable to a user of the electronic device. In addition, there is a need for reducing the junction temperature of a heat generating region.

### SUMMARY

Various features relate a heat dissipating device, and more specifically to a multi-phase heat dissipating device for an electronic device.

An example provides a device that includes a region comprising an integrated device and a heat dissipating device coupled to the region comprising the integrated device. The heat dissipating device is configured to dissipate heat away from the region. The heat dissipating device includes a fluid, an evaporator configured to evaporate the fluid, a condenser configured to condense the fluid, an inner wall coupled to the evaporator and the condenser, an outer shell encapsulating the fluid, the evaporator, the condenser and the inner wall, an evaporation portion configured to channel an evaporated fluid from the evaporator to the condenser, wherein the evaporation portion is at least partially defined by the inner wall, and a collection portion configured to channel a condensed fluid from the condenser to the evaporator, wherein the collection portion is at least partially defined by the inner wall. The inner wall is a separation wall that prevents fluid leaving from the evaporator from mixing with fluid leaving from the condenser.

Another example provides a device that includes a region comprising an integrated device and a heat dissipating means coupled to the region comprising the integrated device. The heat dissipating means is configured to dissipate heat away from the region. The heat dissipating means includes a fluid, a means for evaporating configured to evaporate the fluid, a means for condensing configured to condense the fluid, an inner wall coupled to the means for evaporating and the means for condensing, an outer shell encapsulating the fluid, the means for evaporating, the means for condensing and the inner wall, an evaporation portion configured to channel an evaporated fluid from the means for evaporating to the means for condensing, where the evaporation portion is at least partially defined by the inner wall, and a collection portion configured to channel a condensed fluid from the means for condensing to the means for evaporating, where the collection portion is at least partially defined by the inner wall. The inner wall is a separation wall that prevents fluid leaving from the means for evaporating from mixing with fluid leaving from the means for condensing.

Another example provides a method for fabricating a device. The method assembles a device that includes a region. The method provides an integrated device in the region of the device. The method forms a heat dissipating device. Forming the heat dissipating device includes forming an evaporator configured to evaporate a fluid; forming a condenser configured to condense the fluid; forming an inner wall and coupling the inner wall to the evaporator and the condenser, where the inner wall is a separation wall that prevents fluid leaving from the evaporator from mixing with fluid leaving from the condenser; forming an outer shell that encapsulates, the evaporator, the condenser and the inner wall; forming an evaporation portion configured to channel an evaporated fluid from the evaporator to the condenser, wherein the evaporation portion is at least partially defined by the inner wall; forming a collection portion configured to channel a condensed fluid from the condenser to the evaporator, wherein the collection portion is at least partially defined by the inner wail; and providing the fluid inside the heat dissipating device. The method couples the heat dissipating device to the region comprising the integrated device, the heat dissipating device configured to dissipate heat away from the region.

Another example provides a method for operating a heat dissipating device. The method receives heat from an integrated device, at an evaporator. The method evaporates a fluid at the evaporator based on the received heat. The method channels the evaporated fluid through an evaporation portion to a condenser, where the evaporation portion is at least partially defined by an inner wall. The method condenses the evaporated fluid at the condenser. The method transfers heat away from the fluid through the condenser. The method channels the condensed fluid through a collection portion to the evaporator, where the collection portion is at least partially defined by the inner wall. The inner wall is coupled to the evaporator and the condenser. The inner wall is a separation wall that prevents fluid leaving from the evaporator from mixing with fluid leaving from the condenser.

### DRAWINGS

Various features, nature and advantages may become apparent from the detailed description set forth below when taken in conjunction with the drawings in which like reference characters identify correspondingly throughout.

FIG. 1 illustrates a front view of a mobile device.

FIG. 2 illustrates a back view of a mobile device that includes a heat spreader,

FIG. 3 illustrates a profile view of a mobile device that includes a heat spreader.

FIG. 4 illustrates an internal view of a heat dissipating device.

FIG. 5 illustrates an assembly view of an outer shell of the heat dissipating device.

FIG. 6 illustrates a sequence for fabricating a heat dissipating device.

FIG. 7 illustrates an external view of a heat dissipating device,

FIG. 8 illustrates another external view of a heat dissipating device.

FIG. 9 illustrates a view of how a heat dissipating device coupled to a chip may dissipate heat away from the chip.

FIG. 10 illustrates a view of fluid flow in a heat dissipating device.

FIG. 11 illustrates an assembly view of a device that includes a heat dissipating device coupled to a chip inside the device.

FIG. 12 illustrates a profile view of a device that includes a heat dissipating device coupled to a chip inside the device.

FIG. 13 illustrates a profile view of a heat dissipating device.

FIG. 14 illustrates a profile view of another heat dissipating device,

FIG. 15 illustrates a profile view of another heat dissipating device,

FIG. 16 illustrates a profile view of another heat dissipating device.

FIG. 17 illustrates an angled view of a thermally conductive element that is configured as an evaporator.

FIG. 18 illustrates an angled view of a thermally conductive element that is configured as a condenser.

FIG. 19 (which includes FIGS. 19A-19B) illustrates a sequence for fabricating a thermally conductive element.

FIG. 20 illustrates an assembly view of a cover comprising a heat dissipating device being coupled to a device.

FIG. 21 illustrates a profile view of a cover comprising a heat dissipating device being coupled to a device.

FIG. 22 illustrates a profile view of another cover comprising a heat dissipating device being coupled to a device.

FIG. 23 illustrates a profile view of a cover comprising a heat dissipating device coupled to a device.

FIG. 24 illustrates a sequence for fabricating a cover comprising a heat dissipating device.

FIG. 25 illustrates a view of a heat dissipating device comprising ribs and walls for providing structural support.

FIG. 26 illustrates an exemplary flow diagram of a method for fabricating a heat dissipating device.

FIG. 27 illustrates various electronic devices that may integrate a semiconductor device, an integrated device, a die, an integrated circuit, a PCB and/or a multi-layer heat spreader described herein.

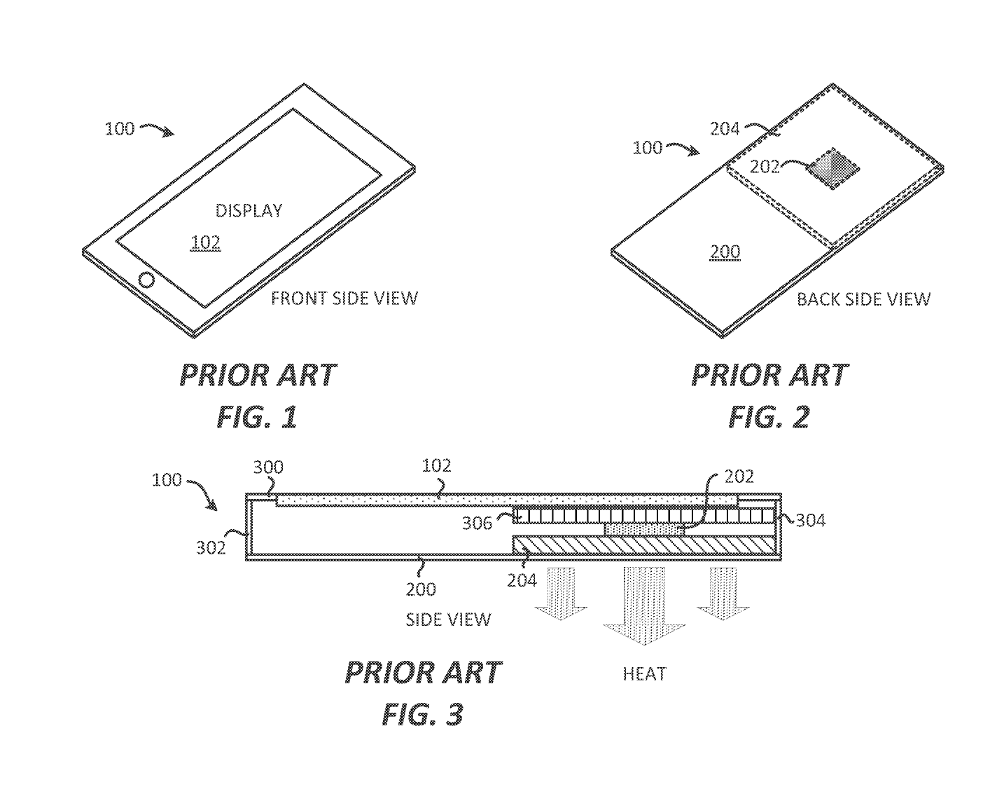

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may or may not be shown in block diagrams in order to avoid obscuring the aspects in unnecessary detail. In other instances, well-known circuits, structures and techniques may not be shown in detail in order not to obscure the aspects of the disclosure.

### Overview

Some implementations provide a device (e.g., mobile device) that includes a region comprising an integrated device (e.g., chip, die), and a heat dissipating device coupled to the region comprising the integrated device. The heat dissipating device may be a multi-phase heat dissipating device. The heat dissipating device is configured to dissipate heat away from the region. The heat dissipating device includes a fluid, an evaporator configured to evaporate the fluid, a condenser configured to condense the fluid, an inner wall coupled to the evaporator and the condenser, an outer shell encapsulating the fluid, the evaporator, the condenser and the inner wall, an evaporation portion configured to channel an evaporated fluid from the evaporator to the condenser, where the evaporation portion is at least partially defined by the inner wall, and a collection portion configured to channel a condensed fluid from the condenser to the evaporator, where the collection portion is at least partially defined by the inner wall. In some implementations, the region may include a thermal interface material (TIM) coupled to the integrated device and the heat dissipating device. In some implementations, the region is a heat generating region configured to generate heat when the device (e.g., mobile device) is operational.

### Exemplary Multi-Phase Heat Dissipating Device

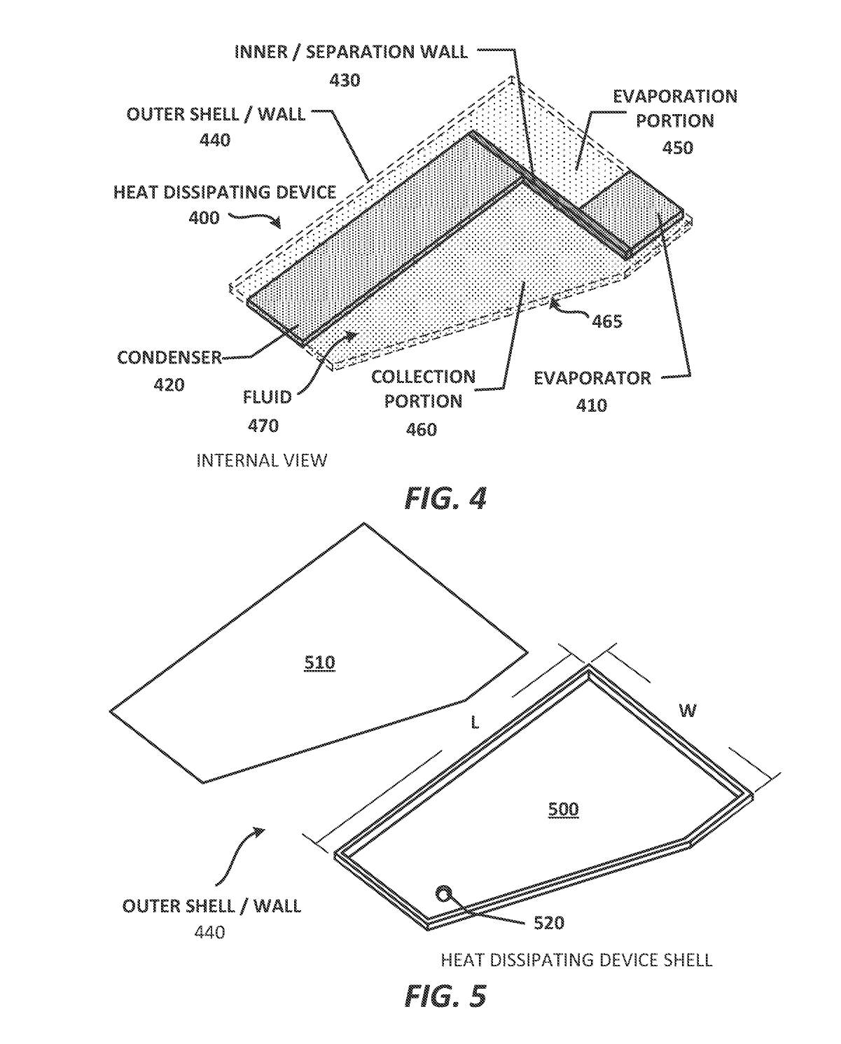

FIG. 4 illustrates a heat dissipating device 400 that includes an evaporator 410, a condenser 420, an inner wall 430, an outer shell 440, an evaporation portion 450, a collection portion 460, and a fluid 470. The evaporator 410 may be a means for evaporating. The condenser 420 may be a means for condensing. The collection portion 460 includes at least one angled portion 465 (e.g., non-orthogonal angled portion). As will be farther described below, the at least one angled portion 465 is configured to help direct fluid towards the evaporator 410 (e.g., through gravity),

In some implementations, the heat dissipating device 400 (e.g., heat dissipating means) is a multi-phase heat dissipating device. As will be further described below, the heat dissipating device 400 may be a cooling device that provides heat dissipation through recirculation of a fluid in the outer shell 440 without the need of a pump or compressor.

The outer shell 440 is configured to encapsulate the evaporator 410, the condenser 420, the inner wall 430, the evaporation portion 450, the collection portion 460, and the fluid 470. The evaporator 410 is coupled to the inner wall 430. The inner wall 430 is coupled to the condenser 420. The evaporation portion 450 of the heat dissipating device 400 is defined by a first surface of the evaporator 410, a first surface of the inner wall 430, a first surface of the condenser 420, and/or a first portion of the outer shell 440. The collection portion 460 of the heat dissipating device 400 is defined by a second surface of the evaporator 410, a second surface of the inner wall 430, and a second surface of the condenser 420 and/or a second portion of the outer shell 440. The inner wall 430 may be a separation wall that prevents fluid leaving the evaporator 410 from mixing with fluid leaving from the condenser 420.

FIG. 4 illustrates the fluid 470 is located inside the heat dissipating device 400. For example, the fluid 470 is located inside the outer shell 440 of the heat dissipating device 400. The fluid 470 is configured to flow inside the heat dissipating device 400. In some implementations, the flow of the fluid 470 inside the heat dissipating device 400 allows for the efficient heat transfer from one portion of the heat dissipating device 400 to another portion of the heat dissipating device 400. For example, the fluid 470 may be configured to allow heat to transfer or flow from the evaporator 410 to the condenser 420. Thus, heat (e.g., from heat generating region, integrated device) coming in through the evaporator 410 may be released through the condenser 420 in some implementations.

FIG. 4 illustrates that the fluid 470 is located in the collection portion 460 of the heat dissipating device 400. However, in some implementations, the fluid 470 may be located in other portions (e.g., the evaporator 410, the condenser 420, the evaporation portion 450) of the heat dissipating device 400. The fluid 470 may have different phases, including a liquid phase and a gas phase. In some implementations, the fluid 470 may be a combination of a liquid phase and a gas phase. In some implementations, a vapor phase of the fluid 470 may be a combination of a liquid phase and a gas phase. In some implementations, the temperature at which the fluid changes from a liquid phase to a gas phase is referred to as the boiling temperature of the fluid. In some implementations, the fluid 470 has a boiling temperature of about 40 Celsius or less. In some implementations, the fluid 470 may be in different phases in different portions of the heat dissipating device 400.

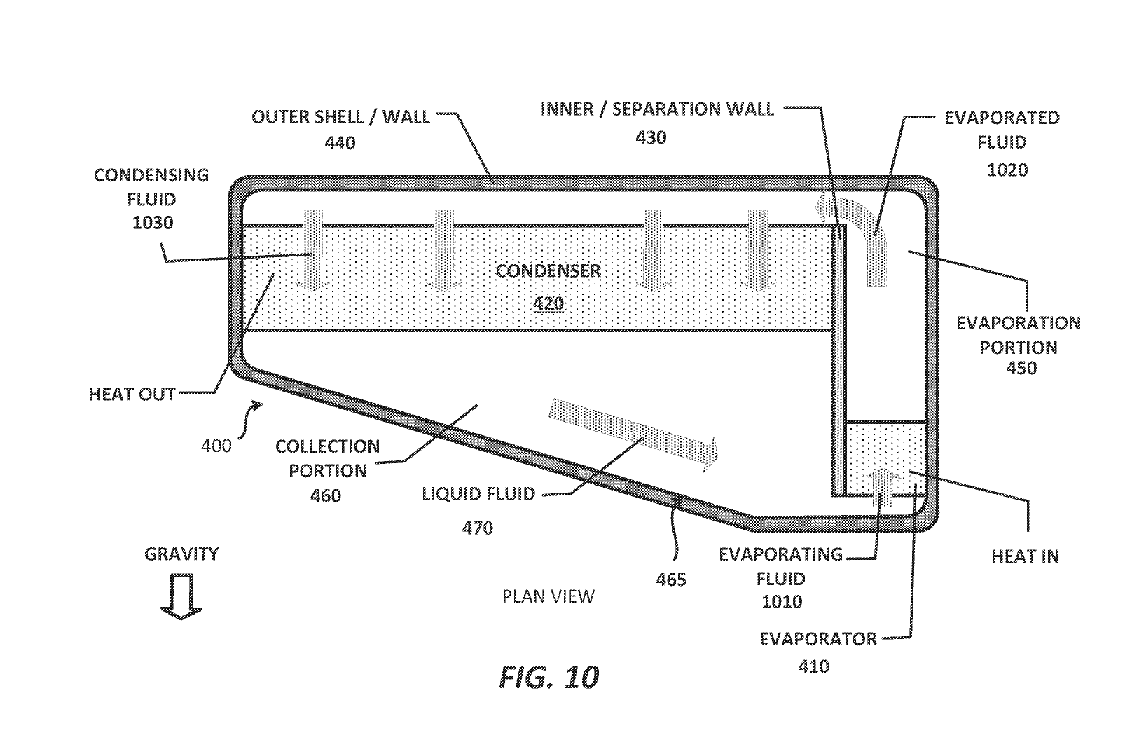

A more detailed example of how the fluid 470 may flow in the heat dissipating device 400, how heat may be dissipated and/or transferred, and the different phases of the fluid 470 are further described and illustrated below in FIG. 10.

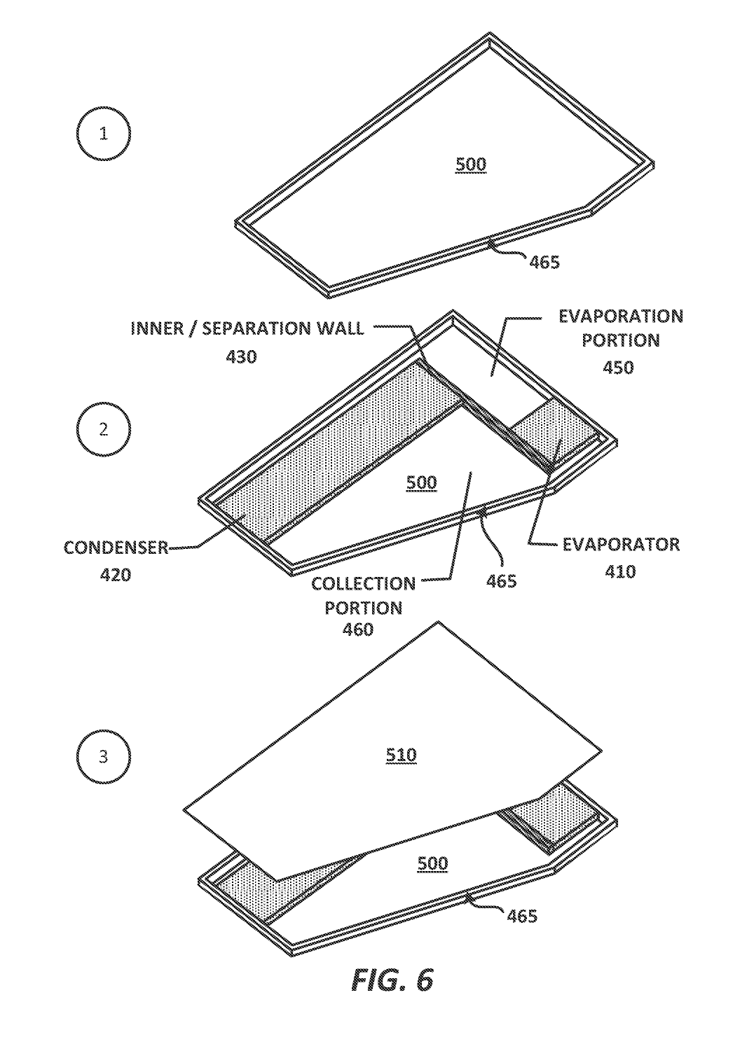

FIG. 5 illustrates an example of an assembly view of the outer shell 440 of the heat dissipating device 400. As shown in FIG. 5, in some implementations, the outer shell 440 may include a first shell 500 and a second shell 510. The first shell 500 may include a base portion and several side walls. The first shell 500 may be a unibody shell or several walls and/or surfaces. The second shell 510 may be a cover configured to couple to the first shell 500 so as to form an enclosure. A coupling process (e.g., welding process, an adhesive process) may be used to couple the second shell 510 to the first shell 500 to form the outer shell 440. As will be further described and illustrated below in FIG. 6, the evaporator 410, the condenser 420, and the inner wall 430 may be formed inside the first shell 500 and the second shell 510. The first shell 500 includes a cavity 520. In some implementations, the cavity 520 is formed so that a fluid (e.g., fluid 470) may be provided in the heat dissipating device 400. After the fluid is provided through the cavity 520, the cavity 520 is sealed to create a sealed (e.g., hermetically sealed) heat dissipating device. It is noted that the cavity may have different shapes and sizes. Moreover, the cavity 520 may be formed in different portions of the first shell 500. In some implementations, the cavity 520 may be formed in the second shell 510. As shown in FIG. 5, the cavity 520 is formed near or around the collection portion 460 of the heat dissipating device. However, in some implementations, the cavity 520 may be formed in other portions (e.g., evaporation portion 450). Although FIG. 5 illustrates a cavity 520, the cavity 520 may be sealed or plugged to prevent fluid from escaping or entering the heat dissipating device. For purpose of clarity, the cavity 520 (or sealed cavity or plug) is not shown in other figures of the present disclosure. However, the cavity 520 (or sealed cavity or plug) may be implemented in any of the heat dissipating devices shown and described in the present disclosure.

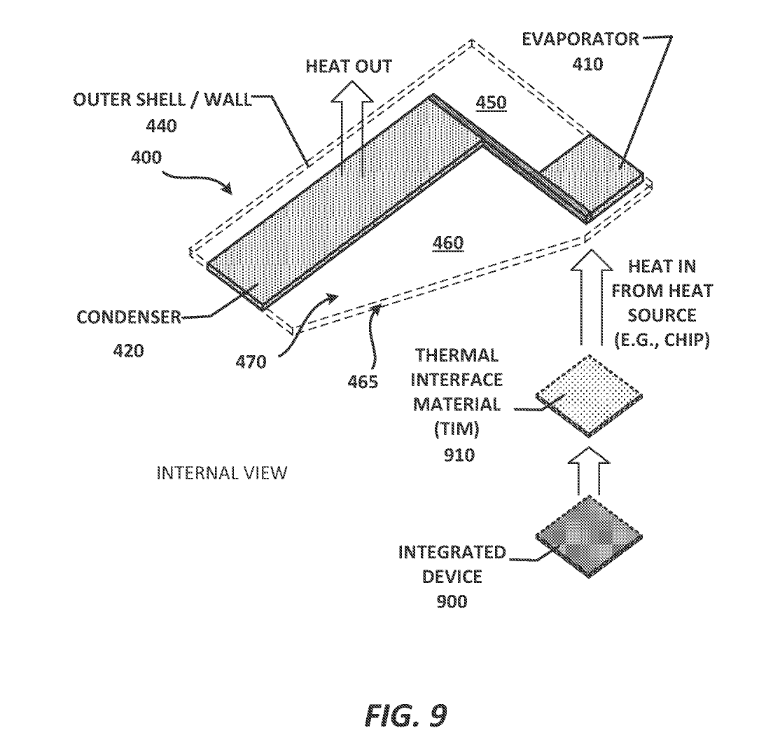

In some implementations, the heat dissipating device 400 is a heat dissipating means configured to be coupled to a region (e.g., heat generating region) of a device (e.g., mobile device) that generates heat. The heat generating region may include an integrated device (e.g., die, chip, package, central processing unit (CPU), graphical processing unit (GPU)). The heat generating region may also include a thermal interface material (TIM) that is coupled to the integrated device. Examples of the heat dissipating device 400 coupled to an integrated device and/or a TIM are further described and illustrated below in at least FIGS. 9, 11 and 12,

Different implementations may use different materials for the heat dissipating device 400, the evaporator 410, the condenser 420, the inner wall 430, the outer shell 440, the evaporation portion 450, the collection portion 460, and the fluid 470. Examples of the different materials that can be used are further described below.

### Exemplary Materials and Fluids

The heat dissipating device 400 and its components may include different materials. In some implementations, the evaporator 410, the condenser 420, the inner wall 430, the outer shell 440 may include a thermally conductive material, such as metal, copper, Aluminum, Aluminum-Nitride (Ceramic), and/or combination thereof.

Table 1 below illustrates exemplary materials and their corresponding properties for materials that may be used in the heat dissipating device 400, or any heat dissipating device described in the present disclosure.

TABLE 1
Exemplary Materials and Properties for components of heat
dissipating device

| | Density | Thermal Conductivity | Specific Heat |
|---|---|---|---|
| Material | (kg/m³) | Value (Watts/m-C) | (Joules/kg-C) |
| Copper | 8933 | 388 | 385 |
| Aluminum | 2707 | 220 | 896 |
| Aluminum—Nitride | 3320 | 177 | 780 |
| (Ceramic) | | | |

A particular thermal conductivity value of a particular material quantities how well or how poorly a particular material conducts heat. Different implementations may also use different fluids in the heat dissipating device 400. Table 2 below illustrates exemplary fluids and their corresponding properties.

TABLE 2
Exemplary Fluids and Properties

| | Liquid | Liquid | | |
|---|---|---|---|---|
| | Density | Viscosity | Latent Heat | Specific Heat |
| Fluid | (kg/m³) | (mPa-s) | (Joules/kg-K) | (Joules/kg-K) |
| Refrigerant | 1218 | 202.3 | 177.8 | 1424.6 |
| R134a | | | | |
| Refrigerant | 1369.8 | 296.5 | 145.9 | 1264.4 |
| R236fa | | | | |
| Refrigerant | 1346.6 | 423.3 | 190.3 | 1264.4 |
| R245fa | | | | |
| Refrigerant | 1165.5 | 209.6 | 167.1 | 1388.7 |
| R1234ze | | | | |

In some implementations, the heat dissipating device 400 may use different combinations of the materials and/or fluids listed above. However, it is noted that other implementations may use different materials and fluids, or combinations thereof than the ones listed above.

The use of the materials and the design of the heat dissipating device in the present disclosure allows for effective and efficient heat transfer or heat removal from a heat generating region of a device. In some implementations, the evaporator 410 may be configured to have a maximum heat transfer coefficient of about 32.8 kW/m²k, in some implementations, the condenser 420 is configured to have a maximum heat transfer coefficient of about 9.27 kW/m²k. However, different implementations may have different maximum heat transfer coefficients.

In some implementations, the evaporator 410 may comprise a critical heat flux at exit of about 26.9 W/cm². In some implementations, the heat dissipating device 400 may be configured to dissipate up to about 18 Watts of heat, which is substantially more than the heat spreader 204 (which is rated at about 3 Watts for mobile devices). In some implementations, the heat dissipating device 400 may be able to dissipate the above mentioned heat while having dimensions that measure about 135 mm (L)×65 mm (W)×0.6 mm (H) or less. Thus, given its dimensions, the heat dissipating device 400 may be implemented in a mobile device to dissipate much more heat than the heat spreader 204.

Having described the structure and components of the heat dissipating device 400, a high level exemplary method for fabricating the heat dissipating device 400 will now be described below.

### Exemplary Sequence for Fabricating a Heat Dissipating Device

FIG. 6 illustrates a high level exemplary sequence for fabricating a heat dissipating device. In some implementations, the sequence may be used to fabricate the heat dissipating device 400 (e.g., heat dissipating means) or any other heat dissipating device described in the present disclose. In some implementations, the order of the sequence may be changed or modified. In some implementations, several processes may be combined as one.

Stage 1 of FIG. 6, illustrates a state after the first shell 500 is provided. In some implementations, providing the first shell 500 includes fabricating a shell that includes several surfaces and walls.

Stage 2 illustrates a state after the evaporator 410, the condenser 420, and the inner wall 430 are coupled to the first shell 500. In some implementations, the evaporator 410, the condenser 420 and/or the inner wall are fabricated separately, assembled together and then coupled to the first shell 500. In some implementations, the evaporator 410, the condenser 420 and/or the inner wall 430 are fabricated concurrently with the first shell 500 (e.g., to form a unibody shell that includes the evaporator 410, the condenser 420 and/or the inner wall 430). In other words, the evaporator 410, the condenser 420 and/or the inner wall 430 may be built together as one piece. An adhesive may be used to couple the evaporator 410, the condenser 420 and/or the inner wall 430 to each other, and/or to the first shell 500. In some implementations, a welding process and/or a mechanical process may be used to couple the evaporator 410, the condenser 420 and/or the inner wall 430 to each other and/or the first shell 500.

As further shown in stage 2, coupling the evaporator 410, the condenser 420 and/or the inner wall 430 to the first shell 500 forms the evaporation portion 450 and the collection portion 460 of a heat dissipating device,

In some implementations, a fluid (e.g., fluid 470) may be provided in at least the collection portion 460. The fluid may flow into different portions of the heat dissipating device (e.g., the evaporator 410, the condenser 420, the evaporation portion 450). The fluid may fill part or all of the heat dissipating device. In some implementations, the fluid may be provided during a different stage of the fabrication process. As described below, the fluid 470 may be provided after the heat dissipating device 400 is fabricated and the fluid 470 is provided through a small cavity (e.g., cavity 520), which is subsequently sealed.

Stage 3 illustrates a state as the second shell 510 is coupled to the first shell 500 to form the outer shell 440 of the heat dissipating device 400. The second shell 510 may be coupled to the first shell 500 through an adhesive, a welding process and/or a mechanical coupling process. The combination of the first shell 500 and the second shell 510 encapsulates the evaporator 410 the condenser 420, the inner wall 430 and/or the fluid 470. In some implementations, the combination of the first shell 500, the second shell 510, the evaporator 410, the condenser 420 and/or the inner wall 430 defines the boundaries of the evaporation portion 450 and the collection portion 460, as well as the heat dissipating device 400.

In some implementations, as mentioned above, some or all of the fluid (e.g., fluid 470) may be provided after the second shell 510 is coupled to the first shell 500. In such instances, a small cavity (e.g., hole) may be formed in the first shell 500 or the second shell 510, so that the fluid may be provided in the heat dissipating device. An example of the cavity is cavity 520 described in FIG. 5. After the fluid is provided through the small cavity (not shown), the small cavity is sealed to create a sealed (e.g., hermetically sealed) heat dissipating device,

### Exemplary Multi-Phase Heat Dissipating Devices

The heat dissipating device 400 may have different configurations. In some implementations, portions of the heat dissipating device 400 may be exposed (e.g., not covered by the outer shell 440), or may be integrated as part of the outer shell 440. In some implementations, the heat dissipating device 400 may be completely positioned outside of the outer shell 440,

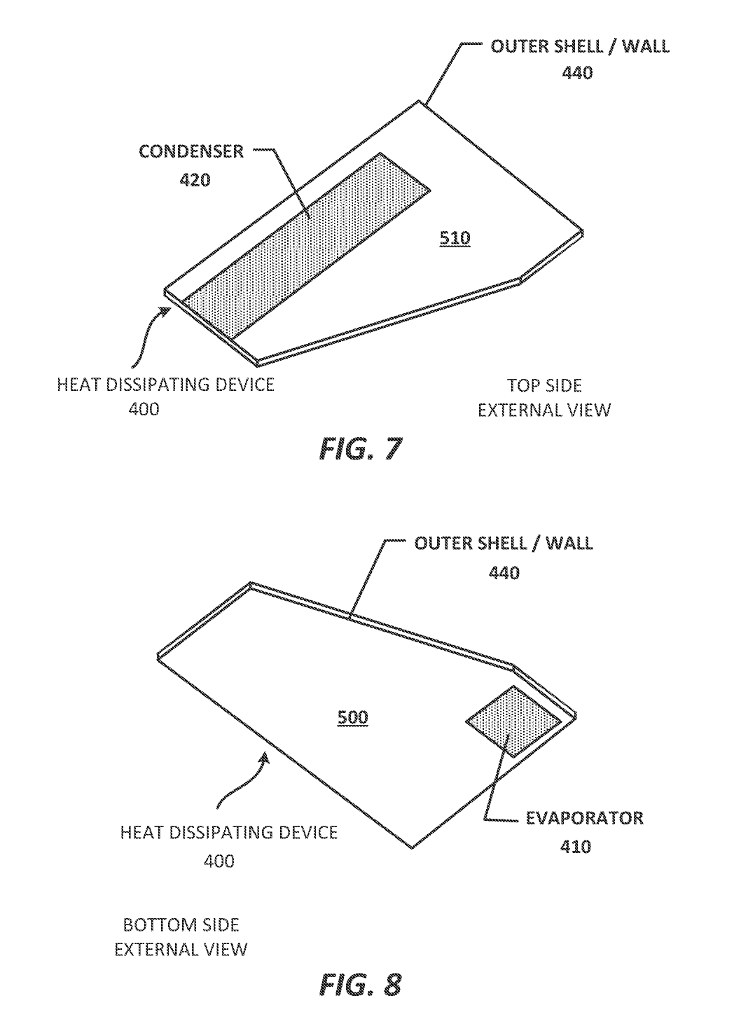

FIG. 7 illustrates the heat dissipating device 400 where a portion (e.g., surface) of the condenser 420 is not covered by the outer shell 440 (e.g., not covered by the second shell 510). In particular, a condenser region (as illustrated by the shaded region) of the condenser 420 is not covered by the outer shell 440. In some implementations, this configuration may provide better heat transfer for the condenser 420. Alternatively, a portion of the condenser 420 may be integrated with the outer shell 440 (e.g., integrated with the second shell 510) such that a surface of the condenser 420 is exposed to an external environment.

FIG. 8 illustrates the heat dissipating device 400 where a portion (e.g., surface) of the evaporator 410 is not covered by the outer shell 440 (e.g., not covered by the first shell 500). In particular, an evaporator region (as illustrated by the shaded region) of the evaporator 410 is not covered by the outer shell 440. In some implementations, this configuration may provide better heat transfer for the evaporator 410. Alternatively, a portion of the evaporator 410 may be integrated with the outer shell 440 (e.g., integrated with the first shell 500) such that a surface of the evaporator 410 is exposed to an external environment.

In some implementations, other portions of the evaporator 410 and/or the condenser 420 may be exposed, not covered by the outer shell 440 and/or integrated with the outer shell 440. The evaporator 410, the condenser 420, and/or the outer shell may be fabricated together or separately.

### Exemplary Heat Flow of Heat Dissipating Device

FIG. 9 illustrates how the heat dissipating device 400 may be utilized to dissipate heat away from a heat generating region of a device (e.g., mobile device). As shown in FIG. 9, the heat dissipating device 400 may be coupled to an integrated device 900 (e.g., die, chip, package, central processing unit (CPU), graphical processing unit (GPU)) through a thermal interface material (TIM) 910. The thermal interface material (TIM) 910 may be an adhesive that couples the heat dissipating device 400 to the integrated device 900. The thermal interface material (TIM) 910 may include appropriate thermal conductivity properties so that heat generated from the integrated device 900 may thermally transfer to the heat dissipating device 400.

The heat dissipating device 400 is placed over the integrated device 900 and the thermal interface material (TIM) 910 such that the evaporator 410 is over the integrated device 900 and the thermal interface material (TIM) 910.

As shown in FIG. 9, heat from the integrated device 900 thermally conducts through the thermal interface material (TIM) 910 and to the evaporator 410. The evaporator 410 is thus heated, which in turns heats the fluid 470 (which is in liquid phase) from the collection portion 460. The fluid 470 that is heated from the evaporator 410 turns into a gas phase or a vapor phase, and then travels from the evaporator 410 through the evaporation portion 450 and to the condenser 420. The inner wall 430 prevents the fluid exiting the evaporator 410 from mixing with fluids exiting the condenser 420.

When the fluid 470 (which is in a gas phase or vapor phase) reaches the condenser 420, heat is transferred away from the fluid 470 through the condenser 420, and escapes out of the heat dissipating device 400. Once the fluid 470 passes through the condenser 420, it returns to liquid phase (e.g., or at least partially liquid phase) into the collection portion 460.

The heat dissipating device 400 may have different configurations. In some implementations, portions of the heat dissipating device 400 may be exposed (e.g., not covered by the outer shell 440), or may be integrated as part of the outer shell 440.

As shown in FIG. 9 and the present disclosure, the condenser 420 has a bigger size than the evaporator 410. In some implementations, this is done to spread out the heat over a bigger area to prevent the device from reaching a critical temperature. In addition, the condenser 420 may have a bigger size than the evaporator 410 to help fully condense the vapors coming from the evaporator 410. For example, the size of the condenser 420 may be selected so that the heat dissipating device 400 dissipates as much heat as possible while still keeping a surface temperature of the device to be less than an acceptable for a user of the device (e.g., mobile device). Thus, by making the condenser 420 larger (e.g., larger surface area) than the evaporator 410, it ensures that the condenser 420 can effectively dissipate the heat through the evaporator while keeping the surface temperature of the device below a threshold temperature and help fully condense the vapors. In addition, by making the condenser 420 larger than the evaporator 410, it helps prevent dry out in the heat dissipating device 400. Dry out occurs when the condenser 420 is not capable of dissipating heat fast enough, thus is not able to fully convert the vapors into condensate liquid (e.g., leaving no liquid fluid or very little of it). When dry out occurs, the fluid inside the heat dissipating device does not flow well resulting in very little recirculation of the fluid in the heat dissipating device 400.

FIG. 10 illustrates a fluid flow of the fluid in the heat dissipating device. More, specifically, FIG. 10 illustrates how the fluid flow inside the heat dissipating device 400 provides efficient heat dissipation of an integrated device. The heat dissipating device 400 provides a cooling device that is capable of recirculating the fluid without the need of a pump or compressor. In some implementations, the recirculation of the fluid inside the heat dissipating device 400 is aided by gravity. Gravity helps improve the heat dissipating capabilities of the heat dissipating device 400 and allows the heat dissipating device 400 to work properly. The heat dissipating device 400 may be designed in such a way as to perform better in certain orientations (e.g., horizontal orientation of the device, vertical orientation of the device). In some implementations, the optimal orientation of the heat dissipating device 400 is one where the evaporator 410 is positioned lower than the condenser 420 and gravity helps fluid flow from the condenser 420, through the collection portion 460 and towards the evaporator 410.

As mentioned above, the collection portion 460 includes at least one angled portion 465. The at least one angled portion 465 may include a non-orthogonal angled portion. The non-orthogonal angled portion is configured, with the help of gravity, to direct the condensed fluid towards the evaporator 410 (e.g., means for evaporating). In some implementations, the collection portion 460 may include one or more non-orthogonal angled portions. A non-orthogonal portion may include different angles. A non-orthogonal portion is a portion (e.g., wall) that includes a non-right angled portion (e.g., wall) relative to an edge of the heat dissipating device 400.

FIG. 10 illustrates the fluid 470 in the collection portion 460 of the heat dissipating device 400. The collection portion 460 has at least one angled portion so that the fluid 470 (which is in liquid form) flows down (e.g., due to gravity) towards the evaporator 410. The evaporator 410 is being heated by a heat generating region (e.g., TIM, integrated device). The collection portion 460 channels the fluid 470 to the evaporator 410. In some implementations, the at least one angled portion helps channels and direct the fluid 470 towards the evaporator 410.

As the fluid 470 enters the evaporator 410 and travels through the evaporator 410, the fluid 470 becomes an evaporating fluid 1010 due to the heat from heat source (e.g., integrated device) that is passed through the evaporator 410 (e.g., heat is transferred from the heat source to the fluid through the evaporator 410). The evaporator 410 is configured so that the pressure drop between the fluid entering the evaporator 410 and the fluid exiting the evaporator 410 is about 0.0049 bar or less. In some implementations, the pressure drop across the evaporator 410 needs to be below 0.0049 bar so that the fluid is not blocked from passing through the evaporator 410, which would block the recirculation of the fluid in the heat dissipating device 400. The above values are merely exemplary. Different designs may have different values.

Once the evaporating fluid 1010 exits the evaporator 410, the evaporating fluid 1010 becomes an evaporated fluid 1020 (e.g., vapor fluid) that travels through the evaporation portion 450 towards the condenser 420. The evaporation portion 450 helps channel the evaporated fluid 1020 towards the condenser 420. The evaporated fluid 1020 may include fluid in a gas phase and some fluid in liquid phase. FIG. 10 illustrates that the inner wall 430 is a separation wall that prevents the evaporated fluid 1020 in the evaporation portion 450 from mixing with the fluid 470 in the collection portion 460.

As the evaporated fluid 1020 enters the condenser 420 (e.g., means for condensing) and travels through the condenser 420, the evaporated fluid 1020 becomes a condensing fluid 1030. This process takes heat away from the evaporated fluid 1020 and through the condenser 420. The heat from the condenser 420 then escapes out of the heat dissipating device 400 (e.g., heat is transferred away from the fluid through the condenser 420 and escapes out of the heat dissipating device 400).

In some implementations, the condenser 420 is configured so that the pressure drop between the fluid entering the condenser 420 and the fluid exiting the condenser 420 is about 0.0002 bar or less. In some implementations, the pressure drop across the condenser 420 needs to be below 0.0002 bar so that the fluid is not blocked from passing through the condenser 420, which would block the recirculation of the fluid in the heat dissipating device 400.

Once the condensing fluid 1030 exits the condenser, the condensing fluid 1030 returns to the collection portion 460 as the fluid 470 (e.g., condensed fluid), in liquid phase, and the cycle repeats itself (e.g., there is recirculation of the fluid).

FIG. 10 illustrates how the heat dissipating device 400 uses recirculation of a fluid to achieve heat dissipation and cooling without the need of a pump or compressor to move the fluid. In some implementations, fluid recirculation in the heat dissipating device 400 is possible through the use of the various designs and/or components of the heat dissipating device 400.

For example, an angled portion (e.g., at least one angled portion 465) may help channel, direct and/or return the condensed liquid (e.g., via gravity) to the evaporator 410.

In another example, the inner wall 430 is a separation wall that prevents the fluid 470 from mixing with the evaporated fluid 1020 (e.g., vapor fluid) in the collection portion 460. It is important that the evaporated fluid 1020 and the fluid 470 are separated so that there is recirculation of the fluid in the heat dissipating device 400.

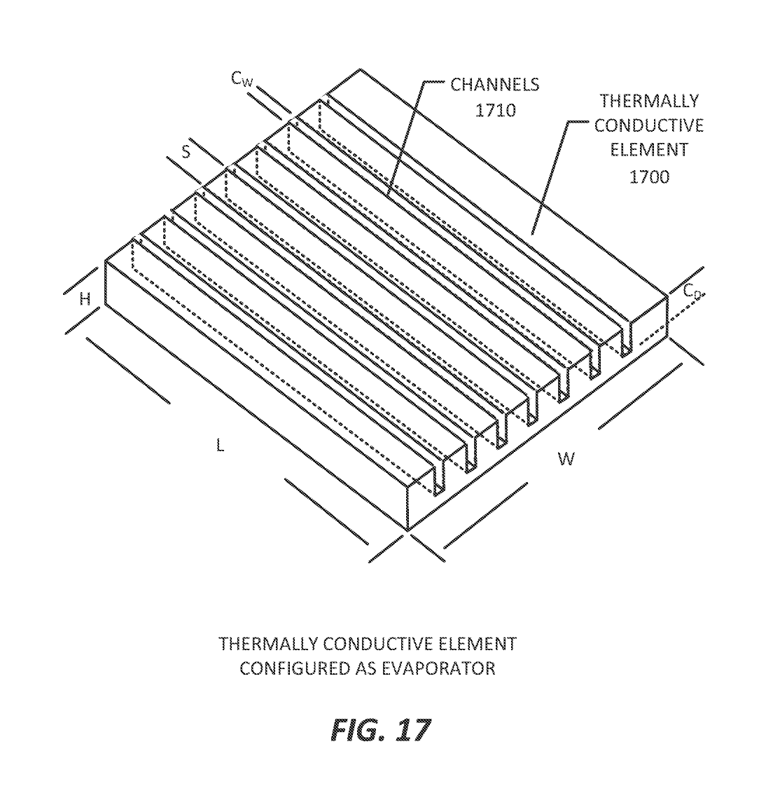

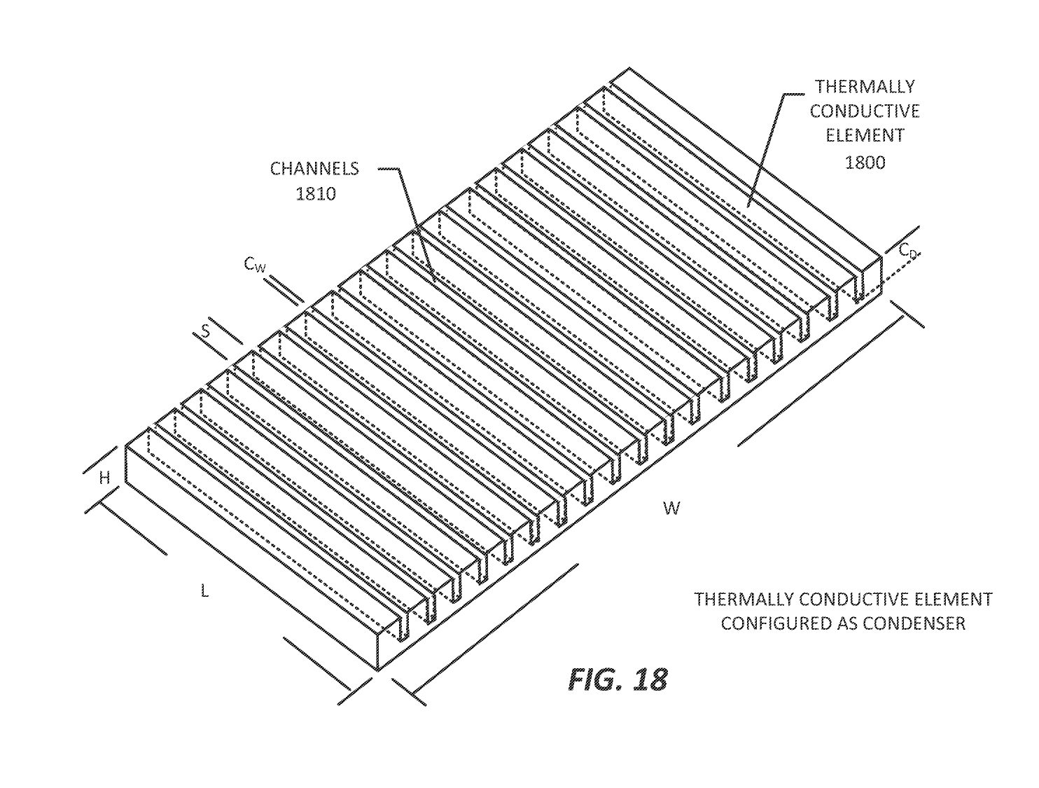

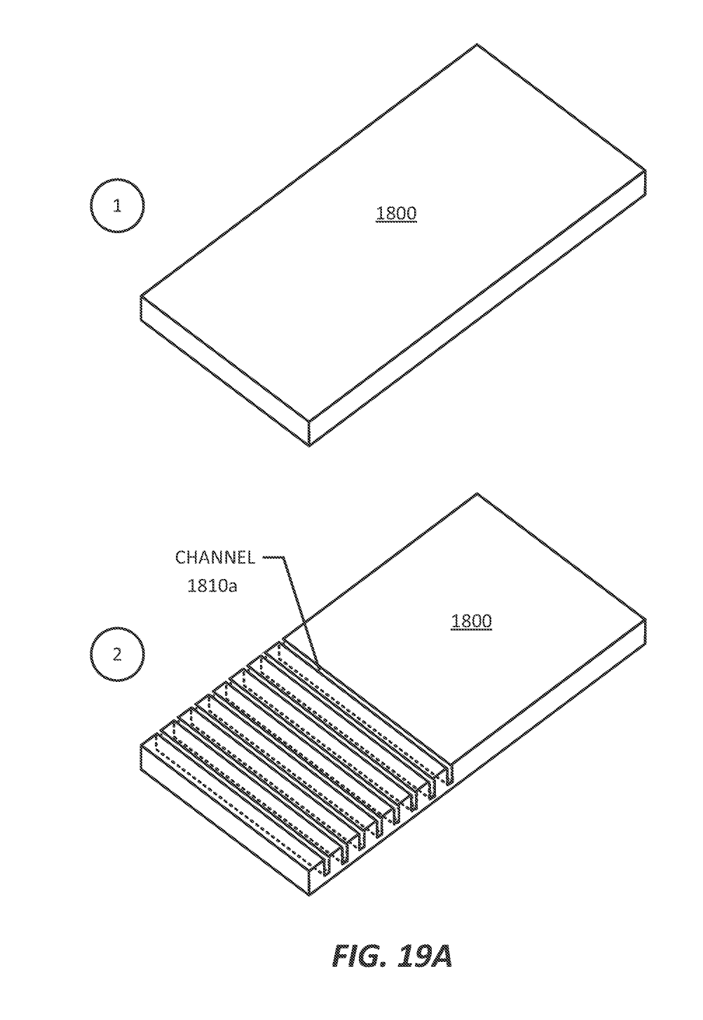

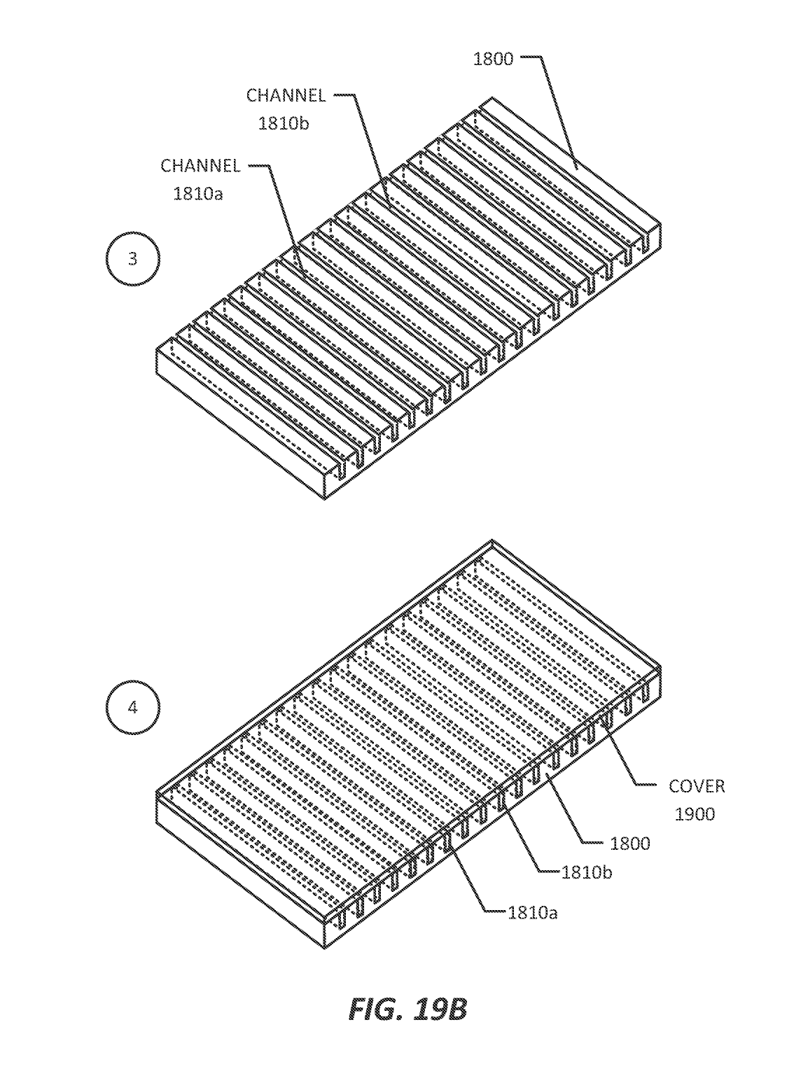

In another example, the evaporator 410 and the condenser 420 are designed in such a way as to minimize the pressure drop as the fluid travels across the evaporator 410 and the condenser 420. The minimizing of pressure drops can be achieved by selecting appropriate dimensions for the channels in which the fluid travels through. Examples of dimensions for the channels for the evaporator 410 and the condenser 420 are described below in at least FIGS. 17-18.

In another example, the dimensions of the evaporator 410 and the condenser 420 are selected so as to prevent dry out in the heat dissipating device 400. As mentioned above, dry out is when the condenser 420 is not dissipating heat fast enough in the heat dissipating device 400 (relative to how fast heat is coming in from the evaporator 410), causing the fluid in heat dissipating device 400 to turn into a gas phase (with little or no liquid phase). When dry out occurs, little recirculation occurs. Examples of dimensions for the evaporator 410 and the condenser 420 are described below in at least FIGS. 17-18.

In some implementations, the heat dissipating device 400 operates optimally when the heat dissipating device 400 is arranged such that the evaporator 410 is located in a lower position than the condenser 420, so as to take advantage of gravity pulling the fluid 470 towards the evaporator 410. In some implementations, fluid recirculation in the heat dissipating device when the temperature of the fluid is about 40 degree Celsius or higher (e.g., boiling temperature of the fluid). However, fluid recirculation may begin at different temperatures for different implementations, since various fluids boil at different temperatures.

### Exemplary Device Comprising Heat Dissipating Device

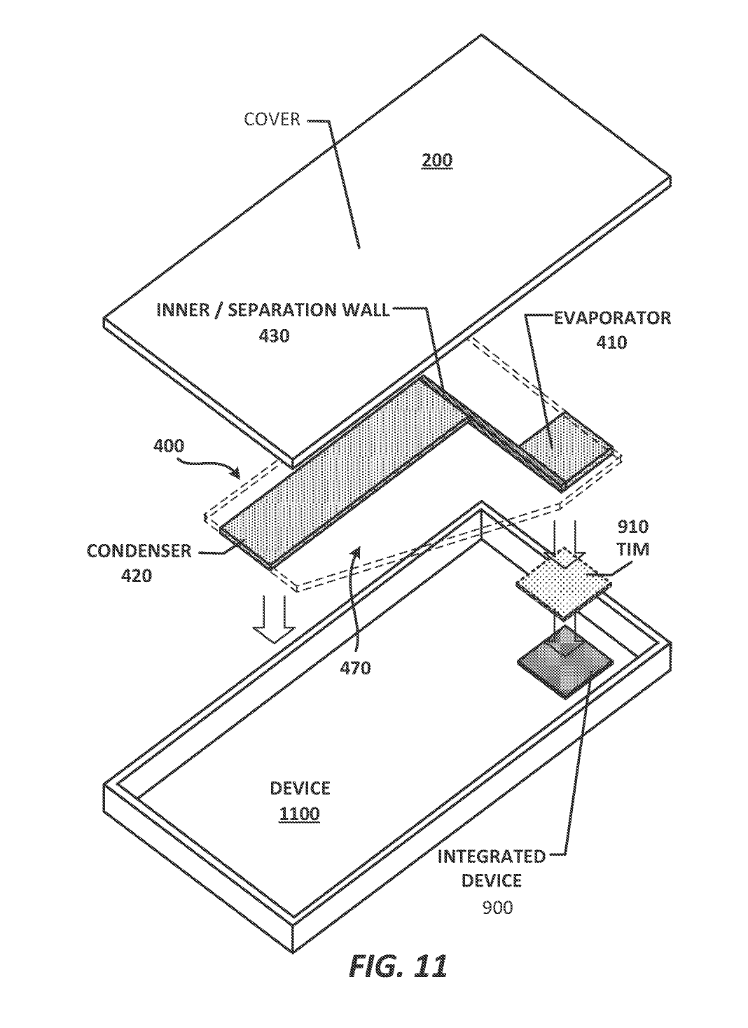

FIG. 11 illustrates an assembly view of a device 1100 that includes the heat dissipating device 400, the integrated device 900 and the thermal interface material (TIM) 910. The device 1100 may be a mobile device (e.g., phone, tablet). As shown in FIG. 11, the heat dissipating device 400 includes the evaporator 410, the condenser 420, the inner wall 430, the outer shell 440, the evaporation portion 450, the collection portion 460, and the fluid 470.

As shown in FIG. 11, the integrated device 900 is coupled to the thermal interface material (TIM) 910, which is coupled to the heat dissipating device 400. In particular, the heat dissipating device 400 is coupled to a portion of the outer shell 440 that is nearest to the evaporator 410.

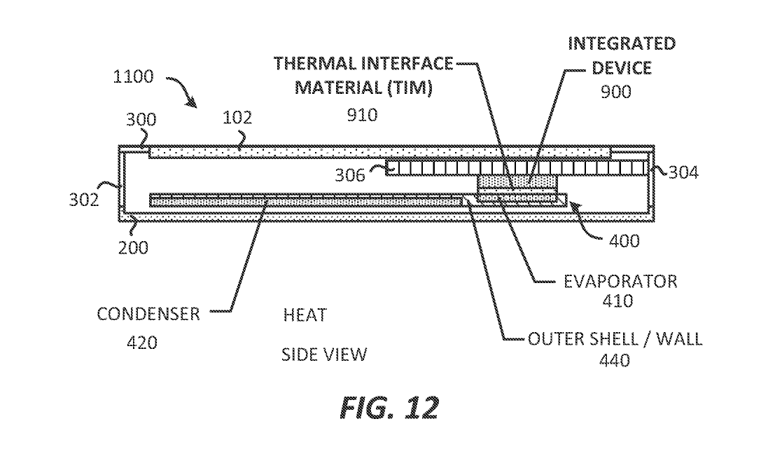

FIG. 12 illustrates a profile view of the device 1100. The device 1100 includes the display 102, the back side surface 200, the front side surface 300, the bottom side surface 302, and the top side surface 304. FIG. 11 also illustrates a printed circuit hoard (PCB) 306, the integrated device 900, the thermal interface material (TIM) 910, and the heat dissipating device 400 inside the device 1100, FIG. 12 illustrates that the heat dissipating device 400 is not touching the back side surface 200 of the device 1100. However, in some implementations, the heat dissipating device 400 may touch the back side surface 200. In some implementations, the heat dissipating device 400 may be coupled to a heat spreader.

### Exemplary Heat Dissipating Devices

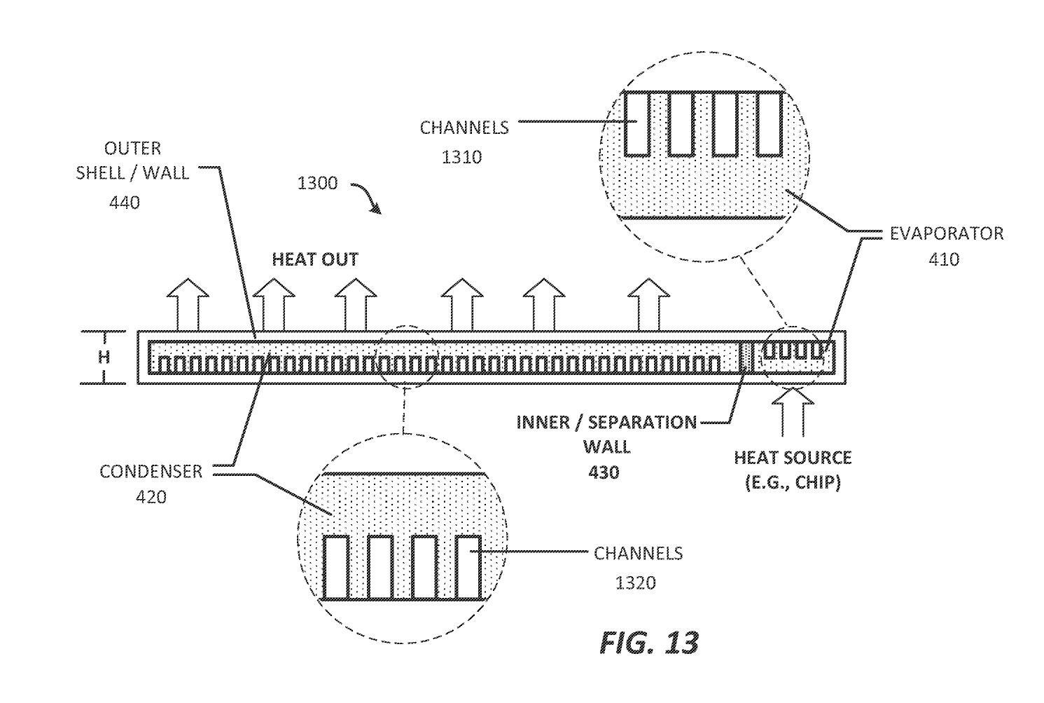

FIGS. 13-16 illustrate profile views of various heat dissipating devices with different configurations. The heat dissipating devices (e.g., 1300-1600) shown in FIGS. 13-16 may be more detailed examples of the heat dissipating device 400.

FIG. 13 illustrates a heat dissipating device 1300 that includes the evaporator 410, the condenser 420, the inner wall 430, and the outer shell 440. As shown in FIG. 13, the evaporator 410 includes channels 1310 (e.g., evaporator channel) in a thermally conductive element. The channels 1310 allow the fluid (e.g., fluid 470) to flow through. The channels 1310 are formed on an upper portion of the evaporator 410 and/or on an upper portion of the heat dissipating device 400. The channels 1310 may be defined by the outer shell 440.

The condenser 420 includes channels 1320 (e.g., condenser channels) in a thermally conductive element. The channels 1320 allow the fluid (e.g., evaporated fluid 1020 and condensing fluid 1030) to flow through. The channels 1320 are formed on a lower portion of the condenser 420 and/or a lower portion of the heat dissipating device 400. The channels 1320 may be defined by the outer shell 440.

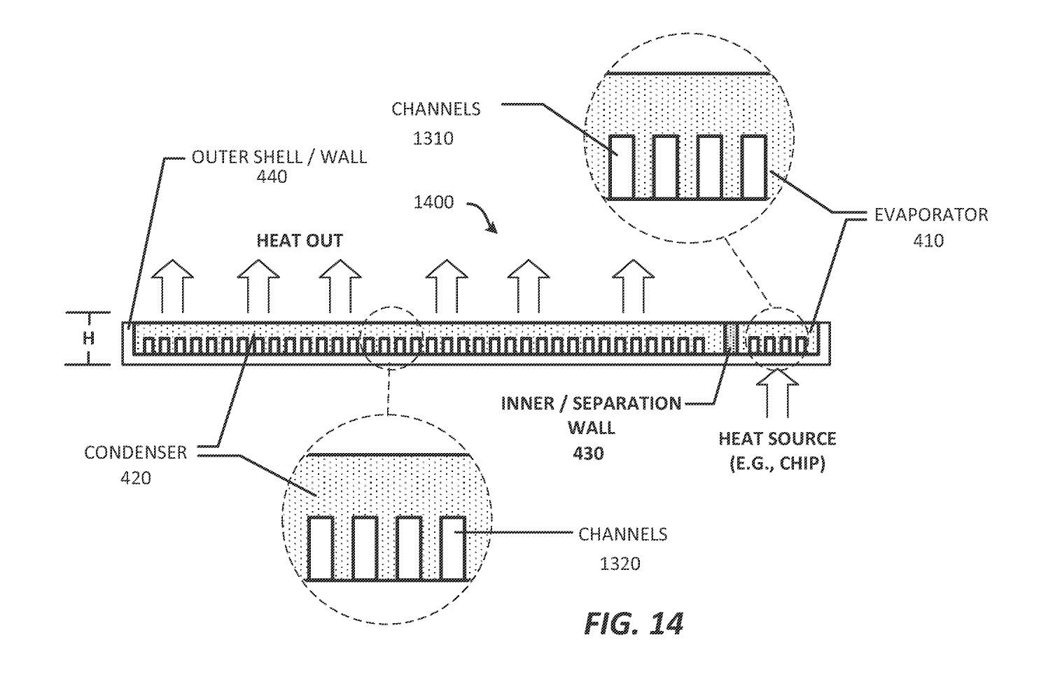

FIG. 14 illustrates a heat dissipating device 1400 that includes the evaporator 410, the condenser 420, the inner wall 430, and the outer shell 440. As shown in FIG. 14, the evaporator 410 includes channels 1310 (e.g., evaporator channel) in a thermally conductive element. The channels 1310 allow the fluid (e.g., fluid 470) to flow through. The channels 1310 are formed on a lower portion of the evaporator 410 and/or on a lower portion of the heat dissipating device 400. The channels 1310 may be defined by the outer shell 440.

The condenser 420 includes channels 1320 (e.g., condenser channels) in a thermally conductive element. The channels 1320 allow the fluid (e.g., evaporated fluid 1020 and condensing fluid 1030) to flow through. The channels 1320 are formed on a lower portion of the condenser 420 and/or a lower portion of the heat dissipating device 400. The channels 1320 may be defined by the outer shell 440.

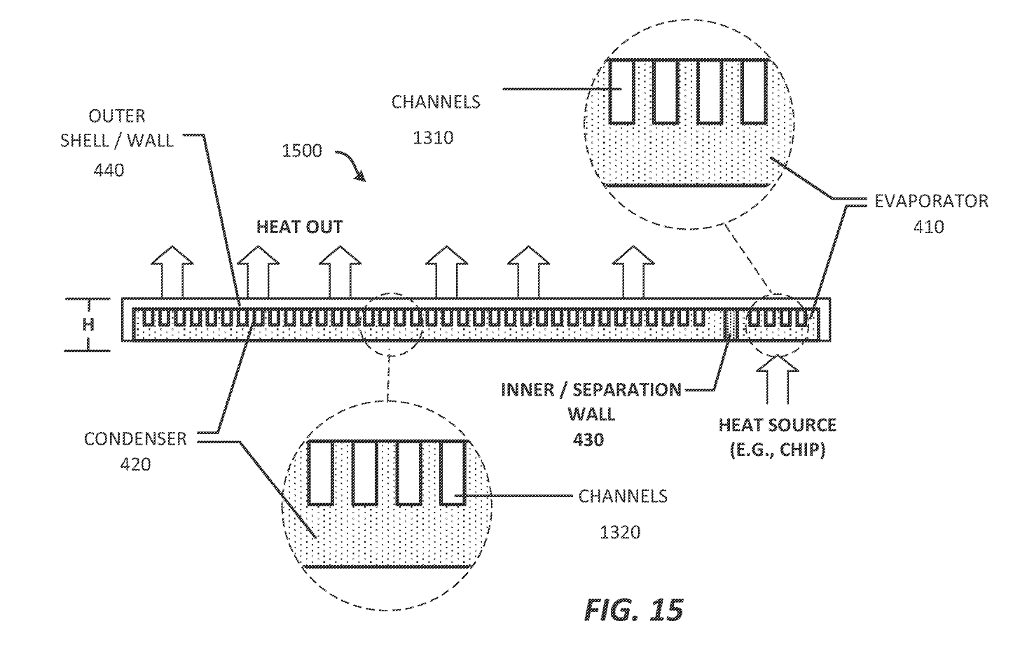

FIG. 15 illustrates a heat dissipating device 1500 that includes the evaporator 410, the condenser 420, the inner wall 430, and the outer shell 440. As shown in FIG. 15, the evaporator 410 includes channels 1310 (e.g., evaporator channel) in a thermally conductive element. The channels 1310 allow the fluid (e.g., fluid 470) to flow through. The channels 1310 are formed on an upper portion of the evaporator 410 and/or on an upper portion of the heat dissipating device 400. The channels 1310 may be defined by the outer shell 440.

The condenser 420 includes channels 1320 (e.g., condenser channels) in a thermally conductive element. The channels 1320 allow the fluid (e.g., evaporated fluid 1020 and condensing fluid 1030) to flow through. The channels 1320 are formed on an upper portion of the condenser 420 and/or an upper portion of the heat dissipating device 400. The channels 1320 may be defined by the outer shell 440.

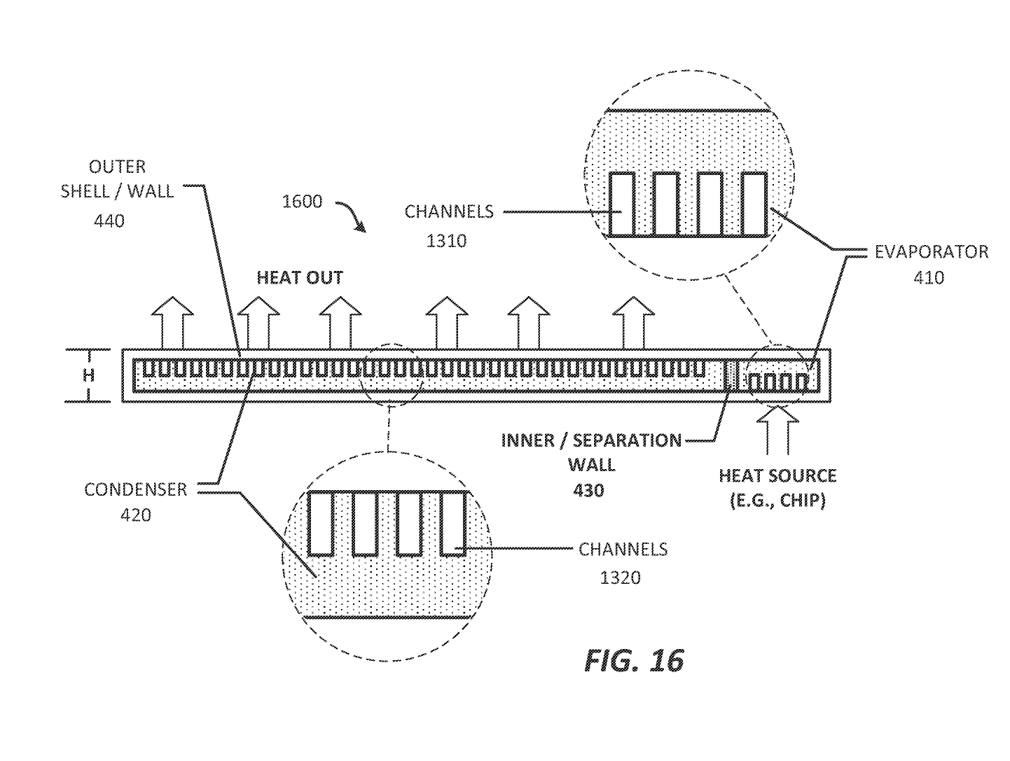

FIG. 16 illustrates a heat dissipating device 1600 that includes the evaporator 410, the condenser 420, the inner wall 430, and the outer shell 440. As shown in FIG. 16, the evaporator 410 includes channels 1310 (e.g., evaporator channel) in a thermally conductive element. The channels 1310 allow the fluid (e.g., fluid 470) to flow through. The channels 1310 are formed on a lower portion of the evaporator 410 and/or on a lower portion of the heat dissipating device 400. The channels 1310 may be defined by the outer shell 440.

The condenser 420 includes channels 1320 (e.g., condenser channels) in a thermally conductive element. The channels 1320 allow the fluid (e.g., evaporated fluid 1020 and condensing fluid 1030) to flow through. The channels 1320 are formed on an upper portion of the condenser 420 and/or an upper portion of the heat dissipating device 400. The channels 1320 may be defined by the outer shell 440.

### Exemplary Thermally Conductive Elements Configured as Evaporator or Condenser

FIG. 17 illustrates a thermally conductive element 1700 that can be configured to operate as an evaporator (e.g., evaporator 410) in a heat dissipating device. FIG. 18 illustrates a thermally conductive element 1800 that can be configured to operate as a condenser (e.g., condenser 420) in a heat dissipating device.

The thermally conductive element 1700 may be made of any of the materials described above in Table 1 and/or in other parts of the disclosure. The thermally conductive element 1700 includes a length (L), a width (W), and a height (H). The thermally conductive element 1700 includes a plurality of channels 1710 that travel along the length of the thermally conductive element 1700. One or more channels from the plurality of channels 1710 may have a width (C_{W}) and a depth (C_{D}). Two or more channels from the plurality of channels 1710 may be separated by a spacing (S),

In some implementations, when the thermally conductive element 1700 is configured to be an evaporator (e.g., evaporator 410), the thermally conductive element 1700 may measure about 20 mm (L)×15 mm (W)×450 microns (μm) (H). In some implementations, the channels 1710 of the thermally conductive element 1700 may be about 300 microns (μm) (C_{W})×250 microns (μm) (C_{D}), when the thermally conductive element 1700 is configured as an evaporator. In some implementations, the dimensions of the channels are selected so that the pressure drop across the thermally conductive element 1700 (e.g., evaporator) is about 0.0049 bar or less.

In some implementations, when the thermally conductive element 1800 is configured to be a condenser (e.g., condenser 420), the thermally conductive element 1800 may measure about 20 mm (L)×120 mm (W)×450 microns (μm) (H). In some implementations, the channels 1810 of the thermally conductive element 1800 may be about 300 microns (μm) (C_{W})×300 microns (μm) (C_{D}), when the thermally conductive element 1800 is configured as a condenser. In some implementations, the dimensions of the channels are selected so that the pressure drop across the thermally conductive element 1800 (e.g., condenser) is about 0.002 bar or less.

The above dimensions are exemplary. Different implementations may use different dimensions.

### Exemplary Sequence for Fabricating a Thermally Conductive Element

FIG. 19 (which includes 19A-19B) illustrates an exemplary sequence for fabricating a thermally conductive element that can be configured as an evaporator (e.g., evaporator 410) or a condenser (e.g., condenser 420) in a heat dissipating device. The sequence of FIG. 19 can be used to fabricate the thermally conductive element 1700 or thermally conductive element 1800. For the purpose of simplification, the sequence of FIG. 19 will be used to describe fabricating the thermally conductive element 1800.

Stage 1 of FIG. 19A, illustrates a thermally conductive element 1800 that is provide (e.g., by a supplier) or fabricated. Different implementations may use different materials for the thermally conductive element 1800. Examples of materials for the thermally conductive element 1800 are listed in Table 1.

Stage 2 illustrates a first plurality of channels 1810a that are formed in the thermally conductive element 1800. The first plurality of channels 1810a may be micro channels that are formed by a plowing process or a micro bonding process. In some implementations, such processes can be used to form channels that have a width of about 300 microns (μm) and, a depth of about 250 microns (μm). However, different implementations may use different dimensions.

Stage 3 of FIG. 19B, illustrates a second plurality of channels 1810b that are formed in the thermally conductive element 1800. The second plurality of channels 1810b may be micro channels that are formed by a plowing process or a micro bonding process, as described above in Stage 2.

Stage 4 illustrates a cover 1900 that is optionally coupled to the thermally conductive element 1800 such the cover 1900 covers the first plurality of channels 1810a and the second plurality of channels 1810b. An adhesive or a welding process may be used to couple the cover 1900 to the thermally conductive element 1800. In some implementations, the cover 1900 may be optional. In some implementations, the cover 1900, the thermally conductive element 1800, the first plurality of channels 1810a and the second plurality of channels 1810b may be configured to operate as an evaporator (e.g., evaporator 410) or a condenser (e.g., condenser 420) for a heat dissipating device.

The cover 1900 is optional because in some implementations, the outer shell 440 may act as the cover for the thermally conductive element (e.g., 1700, 1800).

### Exemplary Device Comprising Heat Dissipating Device

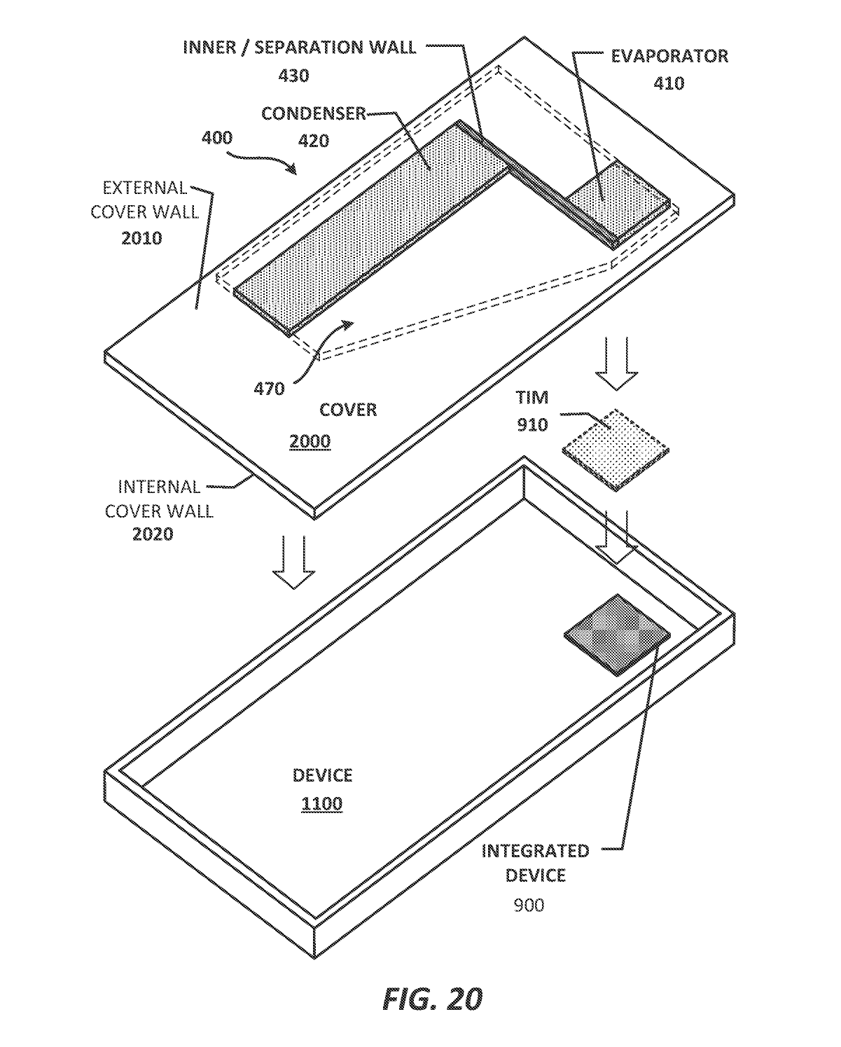

In some implementations, the heat dissipating device may be integrated in a cover and then the cover is coupled to a mobile device. FIG. 20 illustrates an assembly view of a device 1100 (e.g., mobile device) and a cover 2000. The cover 2000 includes the heat dissipating device 400, an external cover wall 2010 and an internal cover wall 2020. The internal cover wall 2020 may be optional. As will be further described below, the cover 2000 may be a shell that encapsulates the heat dissipating device 400. The shell may be filled or unfilled with a material (e.g., plastic) to form the cover 2000. The cover 2000 may be solid cover or a hollow cover.

The device 1100 includes the integrated device 900 and the thermal interface material (TIM) 910. The device 1100 may optionally include a device wall (not shown). The device 1100 may be a mobile device (e.g., phone, tablet).

As shown in FIG. 20, the heat dissipating device 400 includes the evaporator 410, the condenser 420, the inner wall 430, the outer shell 440, the evaporation portion 450, the collection portion 460, and the fluid 470. The heat dissipating device 400 is integrated in the cover 2000.

As shown in FIG. 20, the integrated device 900 is coupled to the thermal interface material (TIM) 910, which is coupled to the heat dissipating device 400 (which is located in the cover 2000). In particular, the heat dissipating device 400 is coupled to a portion of the outer shell 440 that is nearest the evaporator 410.

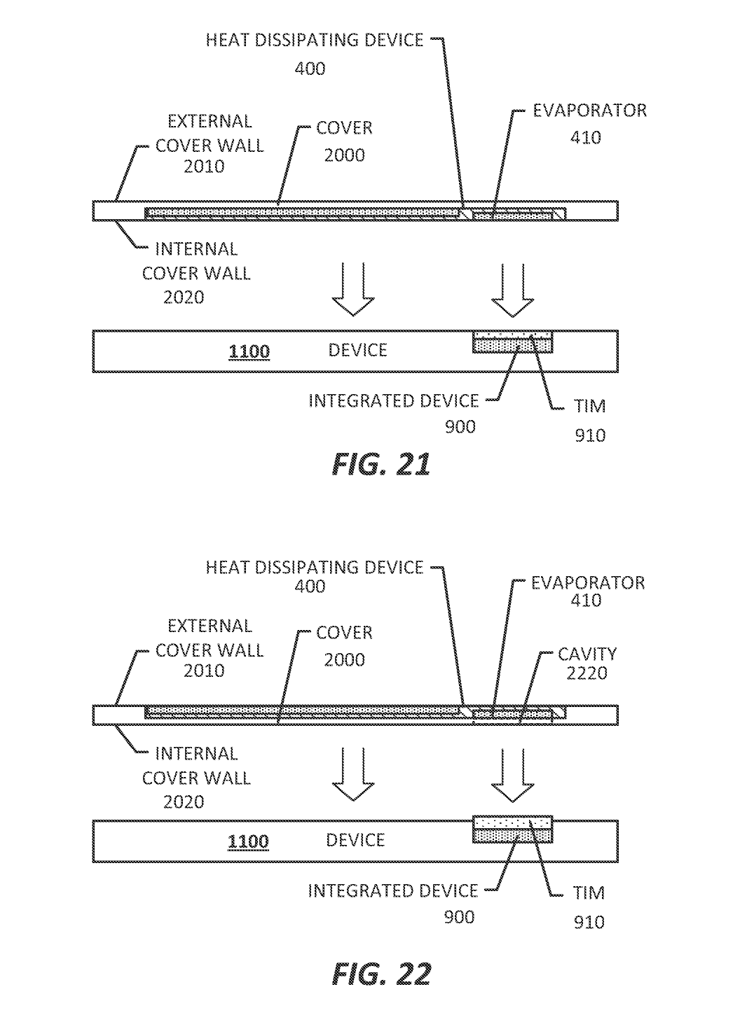

FIGS. 21 and 22 illustrate examples of different covers being coupled to a device. FIG. 21 illustrates the cover 2000 that includes the heat dissipating device 400. As shown in FIG. 21, a surface of the heat dissipating device 400 is substantially aligned or substantially co-planar with the surface of the internal cover wail 2020 of the cover 2000. The cover 2000 is coupled to device 1100 such that the evaporator 410 is coupled to the thermal interface material (TIM) 910. As shown in FIG. 21, the thermal interface material (TIM) 910 is coupled to the integrated device 900.

FIG. 22 illustrates the cover 2000 that includes the heat dissipating device 400, where a surface of the heat dissipating device 400 is substantially aligned with a surface of the external cover wall 2010. FIG. 22 also illustrates that a surface of the heat dissipating device 400 is not aligned with the internal cover wall 2020 of the cover 2000. As shown in FIG. 22, the cover 2000 includes a cavity 2220 over the evaporator 410. As shown in FIG. 22, the cover 2000 is coupled to the device 1100 such that the evaporator 410 is coupled to the thermal interface material (TIM) 910 through the cavity 2220 of the cover 2000.The thermal interface material (TIM) 910 is coupled to the integrated device 900.

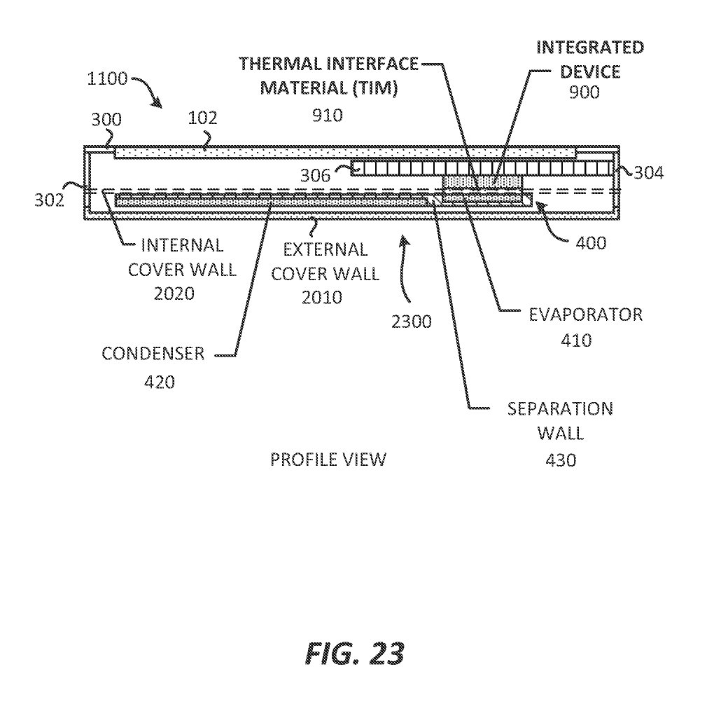

FIG. 23 illustrates a profile view of the cover 2000 coupled to the device 1100. The device 1100 includes the display 102, the cover 2000 (which includes external cover wall 2010 and/or internal cover wall 2020), the front side surface 300, the bottom side surface 302, and the top side surface 304. FIG. 23 also illustrates a printed circuit board (PCB) 306, the integrated device 900, the thermal interface material (TIM) 910. In some implementations, the internal cover wall 2020 is optional.

FIG. 23 illustrates that the heat dissipating device 400 is not touching the external cover wall 2010 of the cover 2000. However, in some implementations, the heat dissipating device 400 may touch the external cover wall 2010. In some implementations, a heat spreader is between the heat dissipating device 400 and the external cover wall.

### Exemplary Sequence for Fabricating a Cover Comprising a Heat Dissipating Device

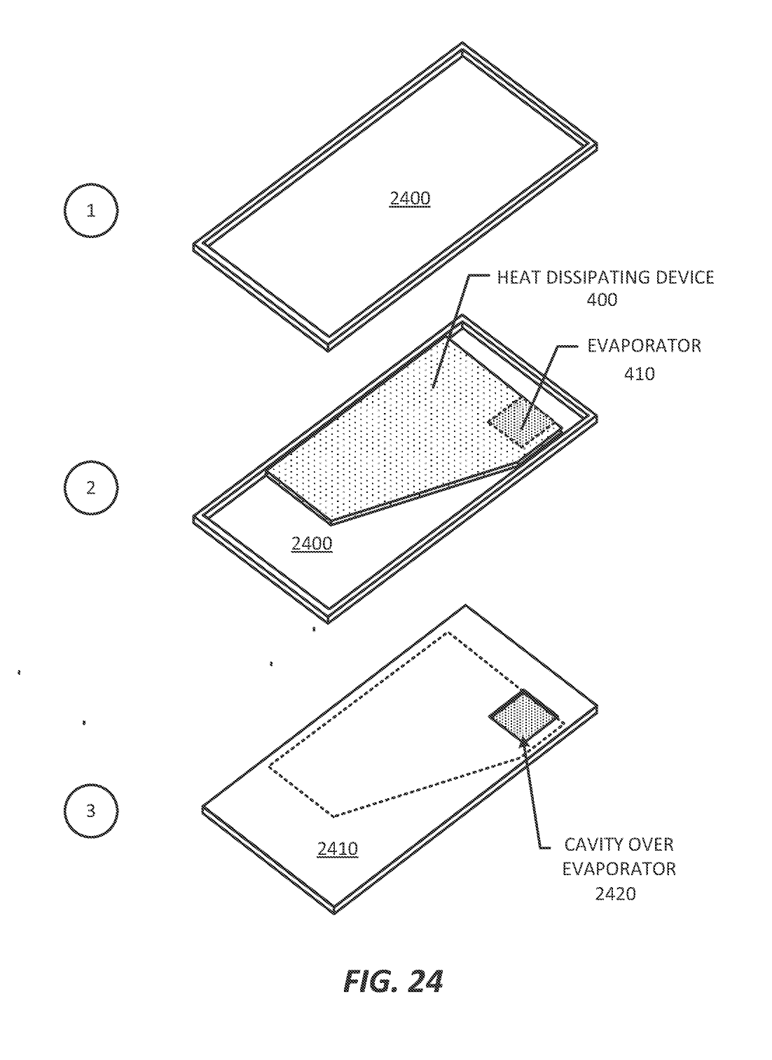

FIG. 24 illustrates an exemplary sequence for fabricating a cover that includes a heat dissipating device. In some implementations, the sequence can be used to fabricate the cover 2000 that includes the heat dissipating device 400.

Stage 1 of FIG. 24, illustrates a cover 2400 that is provided. The cover 2400 may be a shell that includes an external cover wall (e.g., 2010). The cover 2400 has a cavity.

Stage 2 illustrates a heat dissipating device 400 that is placed in the cover 2400. Different implementations may place the heat dissipating device 400 in the cover 2400 differently.

Stage 3 illustrates a layer 2410 over the heat dissipating device 400. The layer 2410 may be used as an internal cover wall (e.g., 2020). The layer 2410 includes a cavity 2220 over the evaporator 410 of the heat dissipating device 400. The cavity 2220 exposes the evaporator 410. The cavity 2220 may include a thermal interface material (TIM) 910, when the cover 2000 is coupled to a device.

In some implementations, the layer 2410 may be a fill material (e.g., plastic) that fills portions of the cover 2400 that is not occupied by the heat dissipating device 400. In some implementations, the layer 2410 is provided such that a surface of the heat dissipating device 400 is substantially aligned or substantially co-planar with a surface of the cover, as shown in FIG. 21. In some implementations, no cover is provided.

### Exemplary Heat Dissipating Devices

In some implementations, the fluid inside the heat dissipating device is heated to very high pressures. High pressures can be problematic and very dangerous because it can result in the heat dissipating device cracking and/or rupturing. Thus, it is important that the heat dissipating device can withstand very internal high pressures (e.g., 16 PSI). The high pressures values will vary based on the different fluids (e.g., refrigerant) used.

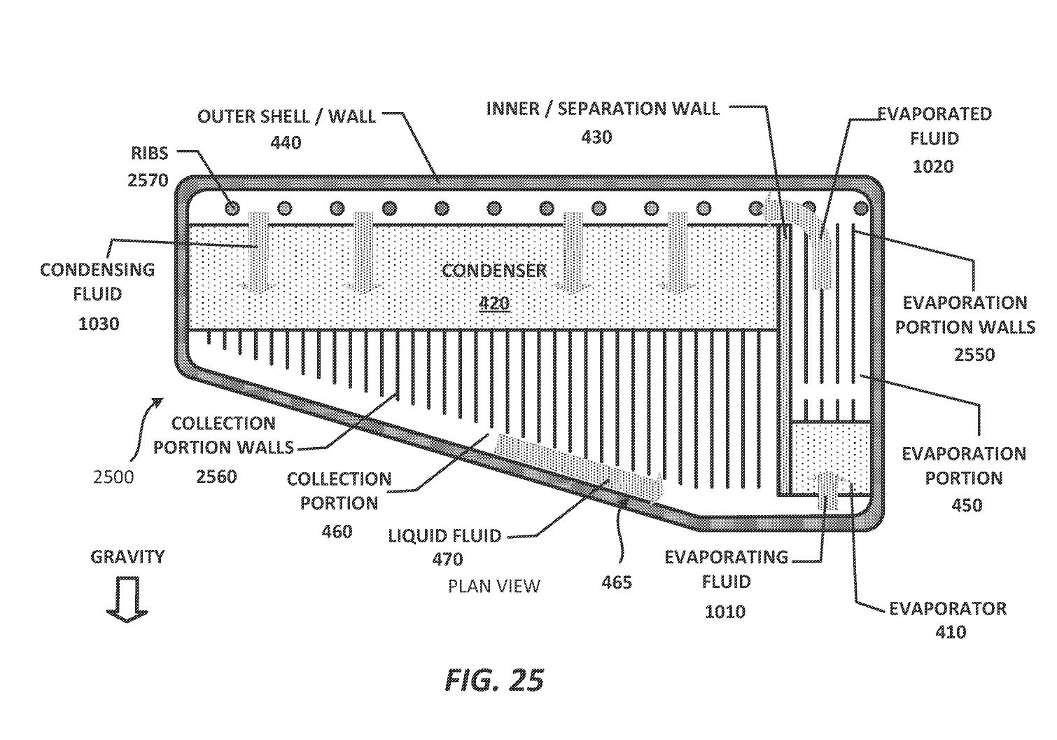

FIG. 25 illustrates an example of a heat dissipating device 2500 that can withstand high internal pressures. The heat dissipating device 2500 includes components and/or structure that are configured to provide structural support for the heat dissipating device. The heat dissipating device 2500 is similar to the heat dissipating device 400, and thus includes similar components as the heat dissipating device 400. The heat dissipating device 2500 also includes one or more evaporation portion walls 2550, one or more collection portion walls 2560 and a plurality of ribs 2570. The fluid (e.g., evaporated fluid 1020) may travel along or through the one or more evaporation portion walls 2550 and a plurality of ribs 2570. The fluid (e.g., fluid 470) may travel along or through the one or more collection portion walls 2560. The heat dissipating device 2500 operates in a similar manner as the heat dissipating device 400, but can operate at higher internal pressures.

The one or more evaporation portion walls 2550, the one or more collection portion walls 2560 and/or the plurality of ribs 2570 are configured to provide additional coupling between the first shell 500 and the second shell 510 of the outer shell 440, thus provide additional structural support to withstand high internal pressure. In some implementations, the one or more evaporation portion walls 2550, the one or more collection portion walls 2560 and/or the plurality of ribs 2570 provide a heat dissipating device 2500 that can withstand about 16 PSI of internal pressure inside the heat dissipating device 2500.

FIG. 25 also illustrates that the evaporation portion walls 2550 subdivide the evaporation portion 450, and the collection portion walls 2560 subdivide the collection portion 460. In some implementations, the flow of the fluid inside the heat dissipating device 2500 is similar to the flow of the fluid inside the heat dissipating device 400. The heat dissipating device 2500 may be a cooling device that provides heat dissipation through recirculation of a fluid in the outer shell 440 without the need of a pump or compressor.

FIG. 25 illustrates the fluid 470 in the collection portion 460 of the heat dissipating device 2500. The collection portion 460 includes the collection portion walls 2560. The collection portion 460 has an angled portion (e.g., 465) so that the fluid 470 (which is in liquid form) flows down (e.g., due to gravity) towards the evaporator 410. The evaporator 410 is being heated by a heat generating region (e.g., region comprising a TIM and/or an integrated device).

As the fluid 470 enters the evaporator 410 and travels through the evaporator 410, the fluid 470 becomes an evaporating fluid 1010 due to the heat from the evaporator 410. Once the evaporating fluid 1010 exits the evaporator 410, the evaporating fluid 1010 becomes an evaporated fluid 1020 (e.g., vapor fluid) that travels through the evaporation portion 450 (e.g., along the evaporation portion walls 2550 and/or ribs 2570) towards the condenser 420. The evaporated fluid 1020 may include fluid in a gas phase and some fluid in liquid phase.

As the evaporated fluid 1020 (e.g., vapor fluid) enters the condenser 420 and travels through the condenser 420, the evaporated fluid 1020 becomes a condensing fluid 1030. This process takes heat away from the evaporated fluid 1020 and into the condenser 420. The heat from the condenser 420 escapes out of the heat dissipating device 2500. Once the condensing fluid 1030 exits the condenser, the condensing fluid 1030 returns to (e.g., via gravity) the collection portion 460 (e.g., along the collection portion walls 2560) as the fluid 470 (e.g., condensed fluid), in liquid phase, and the cycle repeats itself.

In some implementations, as long as the evaporator 410 is being heated by an external heat source or heat generating region, the fluid 470 will cycle through the heat dissipating device 2500 in a manner as described above.

In some implementations, the heat dissipating device 2500 operates optimally when the heat dissipating device 2500 is arranged such that the evaporator 410 is located lower than the condenser 420, so as to take advantage of gravity pulling the fluid 470 towards the evaporator 410 (e.g., without the need of a pump or compressor). As mentioned above, gravity may provide the force that returns the condensed fluid to the collection portion.

It is noted that different implementations may provide a heat dissipating device with different shapes, designs and/or configurations. For example, the evaporator 410 may include one or more evaporators. Similarly, the condenser 420 may include one more condensers.

### Exemplary Method for Fabricating a Heat Dissipating Device

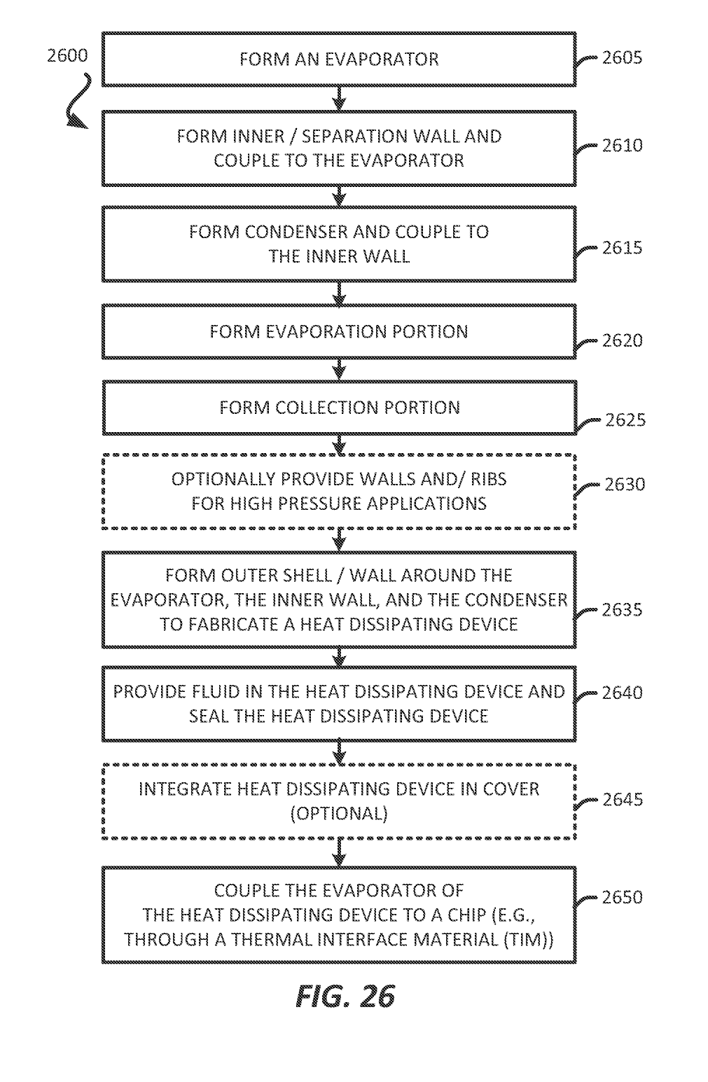

FIG. 26 illustrates a flow chart of an exemplary method 2600 for fabricating a heat dissipating device and coupling the heat dissipating device to a device (e.g., mobile device). The method of FIG. 26 may be used to fabricate any of the heat dissipating devices described in the present disclosure. It is noted the order of the method may be changed and/or modified. In some implementations, some of the processes may be formed concurrently. In some implementations, all of the components described below may be formed from one part and/or material.

The method 2600 for fabricating the heat dissipating device may be performed before, concurrently, or after the device (e.g., mobile) is assembled. For example, the device (e.g., mobile device) may be assembled to include a region, an integrated device may be provided in the region of the device, and the heat dissipating device may be fabricated and coupled to the region that includes the integrated device.

As shown in FIG. 26, the method forms (at 2605) an evaporator (e.g., evaporator 410). An example of forming an evaporator is illustrated in FIGS. 19A-19B.

The method forms (at 2610) an inner wall (e.g., inner wall 430) and couples the inner wall to the evaporator.

The method forms (at 2615) a condenser (e.g., condenser 420) and couples the condenser to the inner wall. An example of forming a condenser is illustrated in FIGS. 19A-19B. In some implementations, the evaporator, the inner wall, and/or the condenser are formed concurrently to form a unibody component.

The method forms (at 2620) an evaporation portion (e.g., evaporation portion 450). In some implementations, the evaporation portion is formed when an outer shell is formed.

The method forms (at 2625) a collection portion (e.g., collection portion 460). In some implementations, the collection portion is formed when an outer shell is formed.

The method optionally forms (at 2630) ribs (e.g., 2570) and/or walls (e.g., 2550, 2560) for high pressure application. These walls and/or ribs provide additional structural support for the heat dissipating device in high pressure application (e.g., 16 PSI). Examples of walls and/or ribs used in high pressure applications are described and illustrated in FIG. 25.

The method forms (at 2635) an outer shell (e.g., outer shell 440) around the evaporator, the inner wall, the condenser to fabricate a heat dissipating device. In some implementations, forming the outer shell also includes forming the evaporation portion, the collection portion, the walls and/or ribs. An example of forming the outer shell is described and illustrated in FIG. 6.

The method provides (at 2640) a fluid (e.g., fluid 470) in the heat dissipating device. In some implementations, the fluid is provided through a small cavity in the outer shell, and the small cavity is subsequently sealed.

The method optionally integrates (at 2645) the heat dissipating device in a cover. Examples of a cover that includes a heat dissipating device are described and illustrated in FIGS. 20-24.

The method couples (at 2650) the heat dissipating device to an integrated device (e.g., chip, die, package) in a device (e.g., mobile device). In some implementations, the heat dissipating device is coupled to the integrated device through a thermal interface material (TIM). In some implementations, the heat dissipating device is coupled to a heat generating region of a device (e.g., through a TIM). In some implementations, when the heat dissipating device is implemented in a cover, the cover comprising the heat dissipating device is coupled to the device comprising the integrated device.

### Exemplary Electronic Devices

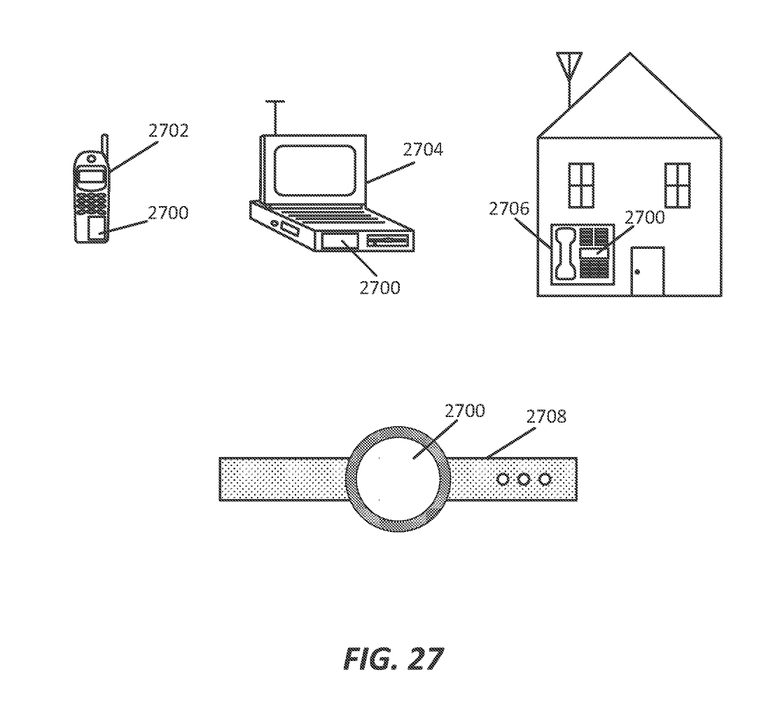

FIG. 27 illustrates various electronic devices that may be integrated with any of the aforementioned heat dissipating device, integrated device, semiconductor device, integrated circuit, die, interposer, package or package-on-package (PoP). For example, a mobile phone device 2702, a laptop computer device 2704, a fixed location terminal device 2706, a wearable device 2708 may include an integrated device 2700 as described herein. The integrated device 2700 may be, for example, any of the integrated circuits, dies, integrated devices, integrated device packages, integrated circuit devices, device packages, integrated circuit (IC) packages, package-on-package devices described herein. The devices 2702, 2704, 2706, 2708 illustrated in FIG. 27 are merely exemplary. Other electronic devices may also feature the integrated device 2700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watch, glasses). Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 4, 5, 6, 7, 8, 9, 10, 11, 12, 13, 14, 15, 16, 17, 18, 19A-19B, 20, 21, 21, 22, 23, 24, 25, 26 and/or 27 may be rearranged and/or combined into a single component, process, feature or function or embodied in several components, processes, or functions. Additional elements, components, processes, and/or functions may also be added without departing from the disclosure. It should also be noted that FIGS. 4, 5, 6, 7, 8, 9, 10, 11, 12, 13, 14, 15. 16, 17, 18. 19A-19B, 20, 21, 21, 22, 23, 24, 25, 26 and/or 27 and its corresponding description in the present disclosure is not limited to dies and/or ICs. In some implementations, FIGS. 4, 5, 6, 7, 8, 9, 10, 11, 12, 13, 14, 15, 16, 17, 18, 19A-19B, 20, 21, 21, 22, 23, 24, 25, 26 and/or 27 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another even if they do not directly physically touch each other.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a region comprising an integrated device; and
a heat dissipating device coupled to the region comprising the integrated device, the heat dissipating device configured to dissipate heat away from the region, wherein the heat dissipating device comprises:
a fluid;
an evaporator configured to evaporate the fluid;
a condenser configured to condense the fluid;
an inner wall coupled to the evaporator and the condenser, wherein the inner wall is a separation wall that prevents fluid leaving from the evaporator from mixing with fluid leaving from the condenser;
an outer shell encapsulating the fluid, the evaporator, the condenser and the inner wall;
an evaporation portion configured to channel an evaporated fluid from the evaporator to the condenser, wherein the evaporation portion is at least partially defined by the inner wall; and
a collection portion configured to channel a condensed fluid from the condenser to the evaporator, wherein the collection portion is at least partially defined by the inner wall.

2. The device of claim 1, wherein the collection portion comprises at least one non-orthogonal angled portion, the at least one non-orthogonal angled portion configured to direct, with the help of gravity, the condensed fluid towards the evaporator.

3. The device of claim 1, wherein the region further comprises a thermal interface material (TIM) coupled to the integrated device and the heat dissipating device.

4. The device of claim 3, wherein the thermal interface material (TIM) is coupled to a portion of the outer shell that is over the evaporator.

5. The device of claim 1, wherein the evaporator comprises a plurality of channels configured to allow the fluid to pass through the evaporator such that the fluid pressure drop across the evaporator is about 0.0049 bar or less.

6. The device of claim 1, wherein the condenser comprises a plurality of channels configured to allow the fluid to pass through the condenser such that the fluid pressure drop across the condenser is about 0.0002 bar or less.

7. The device of claim 1, wherein the evaporator comprises a maximum heat transfer coefficient of about 32.8 kW/m²k and, wherein the condenser comprises a maximum heat transfer coefficient of about 9.27 kW/m²k.

8. The device of claim 1, wherein the heat dissipating device further comprises a plurality of ribs and a plurality of walls in the evaporation portion and the collection portion, wherein the heat dissipating device is configured to withstand about 16 PSI of internal pressure.

9. The device of claim 1, wherein the heat dissipating device is implemented in a cover that is coupled to the device.

10. The device of claim 1, wherein the integrated device is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in a automotive vehicle.

11. An apparatus comprising:
a region comprising an integrated device; and
a heat dissipating means coupled to the region comprising the integrated device, the heat dissipating means is configured to dissipate heat away from the region, wherein the heat dissipating means comprises;
a fluid;
a means for evaporating configured to evaporate the fluid;
a means for condensing configured to condense the fluid;
an inner wall coupled to the means for evaporating and the means for condensing, wherein the inner wall is a separation wall that prevents fluid leaving from the means for evaporating from mixing with fluid leaving from the means for condensing;
an outer shell encapsulating the fluid, the means for evaporating, the means for condensing and the inner wall;
an evaporation portion configured to channel an evaporated fluid from the means for evaporating to the means for condensing, wherein the evaporation portion is at least partially defined by the inner wall; and
a collection portion configured to channel a condensed fluid from the means for condensing to the means for evaporating, wherein the collection portion is at least partially defined by the inner wall.

12. The apparatus of claim 11, wherein the collection portion comprises at least one non-orthogonal angled portion, the at least one non-orthogonal angled portion configured to direct, with the help of gravity, the condensed fluid towards the means for evaporating.

13. The apparatus of claim 11, wherein the region further comprises a thermal interface material (TIM) coupled to the integrated device and the heat dissipating means.

14. The apparatus of claim 13, wherein the thermal interface material (TIM) is coupled to a portion of the outer shell that is over the means for evaporating.

15. The apparatus of claim 11, wherein the means for evaporating comprises a plurality of channels configured to allow the fluid to pass through the means for evaporating such that the fluid pressure drop across the means for evaporating is about 0.0049 bar or less.

16. The apparatus of claim 11, wherein the means for condensing comprises a plurality of channels configured to allow the fluid to pass through the means for condensing such that the fluid pressure drop across the means for condensing is about 0.0002 bar or less.

17. The apparatus of claim 11, wherein the means for evaporating comprises a maximum heat transfer coefficient of about 32.8 kW/m²k and, wherein the means for condensing comprises a maximum heat transfer coefficient of about 9.27 kW/m²k.

18. The apparatus of claim 11, wherein the heat dissipating device further comprises a plurality of ribs and a plurality of walls in the evaporation portion and the collection portion, wherein the heat dissipating device is configured to withstand about 16 PSI of internal pressure.

19. The apparatus of claim 11, wherein the heat dissipating means is implemented in a cover that is coupled to the apparatus.

20. The apparatus of claim 11, wherein the apparatus is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in a automotive vehicle.

21. A method for fabricating a device, comprising:
assembling a device comprising a region;
providing an integrated device in the region of the device;
forming a heat dissipating device, wherein forming the heat dissipating device comprises:
forming an evaporator configured to evaporate a fluid;
forming a condenser configured to condense the livid;
forming an inner wall and coupling the inner wall to the evaporator and the condenser, wherein the inner wall is a separation wall that prevents fluid leaving from the evaporator from mixing with fluid leaving from the condenser;
forming an outer shell that encapsulates, the evaporator, the condenser and the inner wall;
forming an evaporation portion configured to channel an evaporated fluid from the evaporator to the condenser, wherein the evaporation portion is at least partially defined by the inner wall;
forming a collection portion configured to channel a condensed fluid from the condenser to the evaporator, wherein the collection portion is at least partially defined by the inner wall; and
providing the fluid inside the heat dissipating device; and
coupling the heat dissipating device to the region comprising the integrated device, the heat dissipating device configured to dissipate heat away from the region.

22. The method of claim 21, wherein forming the collection portion comprises forming at least one non-orthogonal angled portion for the collection portion, the at least one non-orthogonal angled portion configured to direct, with the help of gravity, the condensed fluid towards the evaporator.

23. The method of claim 21, further comprising a coupling a thermal interface material (TIM) to the integrated device and the heat dissipating device.

24. The method of claim 23, wherein coupling the thermal interface material (TIM) comprises coupling the thermal interface material (TIM) to a portion of the outer shell that is over the evaporator.

25. The method of claim 21, wherein forming the heat dissipating device further comprises forming a plurality of ribs and a plurality of walls in the evaporation portion and the collection portion, wherein the heat dissipating device is configured to withstand about 16 PSI of internal pressure.

26. The method of claim 21, wherein coupling the heat dissipating device comprises implementing the heat dissipating device in a cover that is coupled to the device.

27. A method for operating a heat dissipating device, comprising:
receiving heat from an integrated device, at an evaporator;
evaporating a fluid at the evaporator based on the received heat;
channeling the evaporated fluid through an evaporation portion to a condenser, wherein the evaporation portion is at least partially defined by an inner wall;
condensing the evaporated fluid at the condenser;
transferring heat away from the fluid through the condenser; and
channeling the condensed fluid through a collection portion to the evaporator, wherein the collection portion is at least partially defined by the inner wall,
wherein the inner wail is coupled to the evaporator and the condenser,
wherein the inner wall is a separation wail that prevents fluid leaving from the evaporator from mixing with fluid leaving from the condenser.

28. The method of claim 27, wherein channeling the condensed fluid comprises channeling the condensed fluid along at least one non-orthogonal angled portion of the collection portion, the at least one non-orthogonal angled portion configured to direct, with the help of gravity, the condensed fluid towards the evaporator.

29. The method of claim 27, wherein channeling the evaporated fluid comprises channeling the evaporated fluid through a plurality of ribs in the evaporation portion.

30. The method of claim 27, wherein channeling the evaporated fluid comprises channeling the evaporated fluid through a plurality of walls in the evaporation portion.
